(19) United States
(12) Patent Application Publication
(10) Pub. No.: US 2024/0014350 A1
(43) Pub. Date: Jan. 11, 2024

(54) DISPLAY DEVICE AND METHOD FOR MANUFACTURING THE SAME

(71) Applicant: Samsung Display Co., LTD., Yongin-si (KR)

(72) Inventors: Sung Won CHO, Yongin-si (KR); Soo Chul KIM, Yongin-si (KR); Dae Ho SONG, Yongin-si (KR); Eok Yi LEE, Yongin-si (KR); Jae Ho CHOI, Yongin-si (KR)

(21) Appl. No.: 18/127,555

(22) Filed: Mar. 28, 2023

(30) Foreign Application Priority Data
Jul. 11, 2022 (KR) 10-2022-0085017

(51) Int. Cl. H01L 33/38; H01L 33/10; H01L 33/62; H01L 25/075; H01L 33/50

(52) U.S. Cl. CPC H01L 33/382; H01L 33/10; H01L 33/62; H01L 25/0753; H01L 33/505; H01L 2933/0016; H01L 2933/0066; H01L 2933/0041

(57) ABSTRACT

A display device includes: a substrate; pixel electrodes on the substrate; light emitting elements on the pixel electrodes and extending in a thickness direction of the substrate; a first insulating layer extending around sides of the light emitting element; and a connection electrode between one of the pixel electrodes and a corresponding one of the light emitting elements. The connection electrode includes: a connection portion bonding the pixel electrode to the light emitting element; and a reflection portion integral with the connection portion and extending around the sides of the light emitting element on the first insulating layer.

### CROSS-REFERENCE TO RELATED APPLICATION

This application claims priority to and the benefit of Korean Patent Application No. 10-2022-0085017, filed on Jul. 11, 2022, in the Korean Intellectual Property Office, the entire content of which is incorporated herein by reference.

### BACKGROUND

### 1. Field

Aspects of embodiments of the present disclosure relate to a display device and a method for manufacturing the same.

### 2. Description of the Related Art

With the advancement of multimedia, display devices have become increasingly important. Accordingly, various types of display devices, such as an organic light emitting diode (OLED) display device and a liquid crystal display (LCD) device, have been developed.

A display panel, such as an organic light emitting diode display panel and a liquid crystal display panel, is part of a display device for displaying an image. The display device may include a light emitting element to have a light emitting display panel. For example, the light emitting element may be a light emitting diode (LED) including an organic light emitting diode (OLED) that uses an organic material as a light emitting material or an inorganic light emitting diode that uses an inorganic material as a light emitting material.

### SUMMARY

Embodiments of the present disclosure provide a display device exhibiting improve light efficiency by including a reflection film (or layer) on a side of a light emitting element, and other embodiments of the present disclosure provide a method for manufacturing such a display device.

Aspects and features of the present disclosure are not limited to those mentioned above and additional aspects and features of the present disclosure, which are not mentioned herein, will be clearly understood by those skilled in the art from the following description.

According to an embodiment of the present disclosure, a display device includes a substrate, pixel electrodes on the substrate, light emitting elements on the pixel electrodes and extending in a thickness direction of the substrate, a first insulating layer extending around (e.g., surrounding) sides of the light emitting element; and a connection electrode between one of the pixel electrodes and a corresponding one of the light emitting elements. The connection electrode includes a connection portion bonding the pixel electrode to the light emitting element, and a reflection portion integral with the connection portion and extending around (e.g., surrounding) the sides of the light emitting element on the first insulating layer.

The connection portion and the reflection portion may include the same material.

According to another embodiment of the present disclosure, a display device includes a substrate, pixel electrodes on the substrate, light emitting elements on the pixel electrodes and extending in a thickness direction of the substrate, a first insulating layer extending around (e.g., surrounding) sides of the light emitting element and a connection electrode between one of the pixel electrodes and a corresponding one of the light emitting elements. The connection electrode has a connection portion bonding the pixel electrode to the light emitting element and a reflection portion extending around (e.g., surrounding) the sides of the light emitting element on the first insulating layer. The connection portion and the reflection portion include the same material.

According to another embodiment of the present disclosure, a method for manufacturing a display device includes forming a first connection electrode layer on a first substrate, forming a second connection electrode layer on a light emitting material layer on a second substrate, bonding the first connection electrode layer to the second connection electrode layer to form a connection electrode layer, removing the second substrate, forming a mask pattern on the light emitting material layer, etching the light emitting material layer according to the mask pattern to form light emitting elements, forming a first insulating layer on sides of the light emitting element, forming a connection portion by performing sputtering etching on the connection electrode layer, forming a reflection portion by adhering a non-volatile material from the connection electrode layer to the first insulating layer during the sputtering etching, forming a second insulating layer on sides of the connection portion and an upper surface and sides of the reflection portion, forming a common electrode on an upper surface of each of the light emitting elements and the second insulation layer, forming partition walls on a non-light emission area, and forming a wavelength conversion layer on the common electrode between the partition walls. The wavelength conversion layer being configured to convert a wavelength of light emitted from the light emitting element.

In the display device and the method for manufacturing the same according to embodiments of the present disclosure, a reflection film may be formed on a side of a light emitting element by using re-arrangement occurring during sputtering etching of a connection electrode and without using a separate mask.

In the display device and the method for manufacturing the same according to embodiments of the present disclosure, a reflection film is formed on a side of a light emitting element to prevent color mixture due to emission of light from the light emitting element reaching an adjacent light emission area.

Aspects and features of embodiments of the present disclosure are not limited to those mentioned above and more various other aspects and features are included in the following description of the present disclosure.

### BRIEF DESCRIPTION OF THE DRAWINGS

The above and other aspects and features of the present disclosure will become more apparent by describing, in detail, embodiments thereof with reference to the attached drawings, in which:

FIG. 1 is a plan view illustrating a display device according to one embodiment;

FIG. 2 is a schematic layout view illustrating a circuit of a display substrate of a display device according to one embodiment;

FIG. 3 is an equivalent circuit view of one pixel of a display device according to one embodiment;

FIG. 4 is an equivalent circuit view of one pixel of a display device according to another embodiment;

FIG. 5 is an equivalent circuit view of one pixel of a display device according to other embodiment;

FIG. 6 is a schematic cross-sectional view illustrating a display device according to one embodiment;

FIG. 7 is a cross-sectional view illustrating a pixel electrode and a light emitting element according to one embodiment;

FIG. 8 is an enlarged cross-sectional view of a light emitting element shown in FIG. 6 according to one embodiment;

FIG. 9 is an enlarged cross-sectional view of a light emitting element shown in FIG. 6 according to another embodiment;

FIGS. 10 to 31 are cross-sectional views illustrating steps of a method for manufacturing a display device according to one embodiment.

FIG. 32 is a flow chart describing a method for manufacturing a display device according to one embodiment.

FIG. 33 is a view illustrating a virtual reality device including a display device according to one embodiment.

FIG. 34 is a view illustrating a smart device including a display device according to one embodiment.

FIG. 35 is a view illustrating a vehicle dashboard and a center fascia including display devices according to one embodiment.

FIG. 36 is a view illustrating a transparent display device including a display device according to one embodiment.

### DETAILED DESCRIPTION

The present disclosure will now be described more fully hereinafter with reference to the accompanying drawings, in which embodiments of the present disclosure are illustrated. The present disclosure may, however, be embodied in various different forms and should not be construed as being limited to the embodiments described herein. Some aspects of the described embodiments that are not associated with the present disclosure or are well understood by those of ordinary skill in the art may not be described or may only be briefly described to focus the disclosure.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of,” when preceding a list of elements, modify the entire list of elements and do not modify the individual elements of the list. As used herein, the terms “use,” “using,” and “used” may be considered synonymous with the terms “utilize,” “utilizing,” and “utilized,” respectively.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

Further, the phrase “in a plan view” means when an object portion is viewed from above, and the phrase “in a schematic cross-sectional view” means when a schematic cross-section taken by vertically cutting an object portion and viewed from the side. The terms “overlap” or “overlapped” mean that a first object may be above or below or to a side of a second object, and vice versa. Additionally, the term “overlap” may include layering, stacking, face or facing, extending over, covering, or partly covering, or any other suitable term as would be appreciated and understood by those of ordinary skill in the art. The expression “not overlap” may include meanings such as “apart from,” “set aside from,” or “offset from” and any other suitable equivalents as would be appreciated and understood by those of ordinary skill in the art. The terms “face” and “facing” may mean that a first object may directly or indirectly oppose a second object. When a third object intervenes between a first and second object, the first and second objects may be understood as being indirectly opposed to one another although still facing each other.

The terms “about” or “approximately” as used herein is inclusive of the stated value and means within an acceptable range of deviation for the stated value as determined by one of ordinary skill in the art considering the measurement in question and the error associated with measurement of the particular quantity (e.g., the limitations of the measurement system). For example, “about” may mean within one or more standard deviations, or within ±30%, 20%, 10%, 5% of the stated value.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

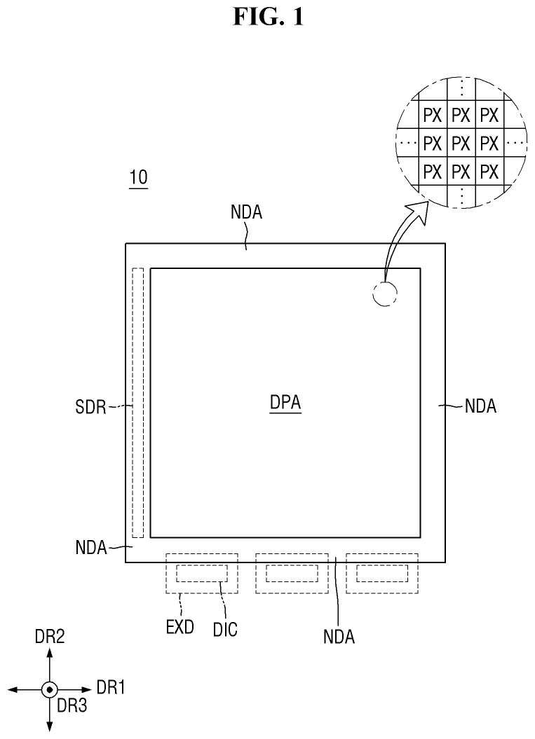

FIG. 1 is a plan view illustrating a display device according to one embodiment of the present disclosure.

Referring to FIG. 1, a display device 10 according to one embodiment may be applied to (or included in) a smartphone, a cellular phone, a tablet PC, a personal digital assistant (PDA), a portable multimedia player (PMP), a television, a game machine, a wristwatch type electronic device, a head mounted display, a monitor of a personal computer, a laptop computer, a vehicle navigator, a vehicle dashboard, a digital camera, a camcorder, an outdoor billboard, an electronic display board, a medical device, an inspection device, various home appliances, such as a refrigerator and a washing machine, or an Internet of Things (IoT) device. In the present disclosure, a television (TV) will be described as an example of a display device, and the TV may have high resolution or ultra-high resolution, such as HD, UHD, 4K, and 8K.

The display device 10, according to embodiments of the present disclosure, may be categorized depending on a display method or type. For example, the display device may include an organic light emitting diode (OLED) display device, an inorganic light emitting display device, a quantum dot light emitting display (QLED) device, a micro-LED display device, a nano-LED display device, a plasma display device (PDP), a field emission display (FED) device, a cathode ray tube (CRT) device, a liquid crystal display (LCD) device, and an electrophoretic display (EPD) device. Hereinafter, the display device will be described as being the organic light emitting diode display device by way of example, and the organic light emitting diode display device applied to the embodiments will simply be abbreviated as the display device unless otherwise noted. However, the present disclosure is not limited to the organic light emitting display device, and another display device listed as above or known in the relevant art may be applied to the present disclosure within the range of technical spirits.

In the following drawings, a first direction DR1 refers to a horizontal direction of the display device 10, a second direction DR2 refers to a vertical direction of the display device 10, and a third direction DR3 refers to a thickness direction of the display device 10. Further, “left”, “right”, “upper,” and “lower” refer to directions when the display device 10 is viewed on a plane. For example, “right side” refers to one side of the first direction DR1, “left side” refers to the other side of the first direction DR1, “upper side” refers to one side of the second direction DR2, and “lower side” refers to the other side of the second direction DR2. Also, “upper side” refers to one side of the third direction DR3, and “lower side” refers to the other side of the third direction DR3 as would be understood from the context of the terms use.

The display device 10, according to one embodiment, may have a square shape on a plan view. When the display device 10 is a television, the display device 10 may have a rectangular shape with a long side extending in a horizontal direction but is not limited thereto. The display device 10 may be provided such that a long side is positioned in (or extends in) a vertical direction or may rotatable such that the long side is variably positioned in a horizontal or vertical direction. Also, in other embodiments, the display device 10 may have a circular shape or an oval shape.

The display device 10 may have a display area DPA and a non-display area NDA. The display area DPA may be an active area in which an image is displayed. The display area DPA may have a square shape on a plan view similar to a general shape of the display device 10 but is not limited thereto.

The display area DPA may include a plurality of pixels PX. The plurality of pixels PX may be arranged in a matrix. Each pixel PX may have a rectangular or square shape on a plane but is not limited thereto. For example, each pixel PX may have a rhombus shape in which each side is inclined with respect to one direction of the display device 10. The plurality of pixels PX may include various colors. For example, the plurality of pixels PX may include, but are not limited to, a first pixel PX of (or emitting) a red color, a second pixel PX of a green color, and a third pixel PX of a blue color. The respective pixels PX may be alternately arranged in a stripe type or a PenTile® (a registered trademark of Samsung Display Co., Ltd.) type.

The non-display area NDA may be disposed in the vicinity of the display area DPA. For example, the non-display area NDA may fully or partially surround (e.g., surround on a plan view of extend around a periphery of) the display area DPA. The display area DPA may have a square shape, and the non-display area NDA may be disposed to be adjacent to the four sides of the square display area DPA. The non-display area NDA may constitute (or form) a bezel of the display device 10.

A driving circuit or a driving element for driving the display area DPA may be disposed in the non-display area NDA. In one embodiment, a pad portion may be provided on a display substrate of the display device 10 in the non-display area NDA disposed to be adjacent to a first side (e.g., the lower side in FIG. 1) of the display device 10, and an external device EXD may be packaged on (e.g., coupled to) a pad electrode of the pad portion. Examples of the external device EXD may include a connection film, a printed circuit board, a driving chip (DIC), a connector, a line connection film, and the like. A scan driver SDR, which is directly formed on the display substrate of the display device 10, may be disposed in the non-display area NDA disposed to be adjacent to a second side (e.g., the left side in FIG. 1) of the display device 10.

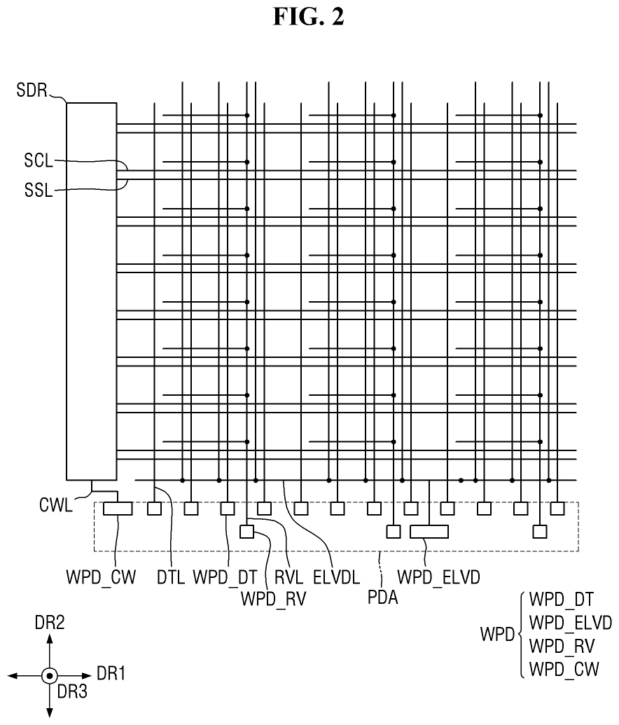

FIG. 2 is a schematic layout view illustrating a circuit of a display substrate of a display device according to one embodiment.

Referring to FIG. 2, a plurality of lines are disposed on a first substrate. The plurality of lines may include a scan line SCL, a sensing signal line SSL, a data line DTL, a reference voltage line RVL, a first power line ELVDL, and the like.

The scan line SCL and the sensing signal line SSL may extend in the first direction DR1. The scan line SCL and the sensing signal line SSL may be connected to the scan driver SDR. The scan driver SDR may include a driving circuit. The scan driver SDR may be disposed at one side of the non-display area NDA on the display substrate but is not limited thereto. In other embodiments, the scan driver SDR may be disposed at both sides (e.g., opposite sides) of the non-display area NDA. The scan driver SDR may be connected to an external device (e.g., ‘EXD’ in FIG. 1) by a signal connection line CWL connected to a pad WPD_CW on the first non-display area NDA and/or the second non-display area NDA.

The data line DTL and the reference voltage line RVL may extend in the second direction DR2 crossing the first direction DR1. The first power line ELVDL may include a portion extending in the second direction DR2. The first power line ELVDL may further include a portion extending in the first direction DR1. The portions of the first power line ELVDL may form a mesh structure, but the first power line ELVDL is not limited thereto.

A wiring pad WPD may be disposed on at least one end of the data line DTL, the reference voltage line RVL, or the first power line ELVDL. Each wiring pad WPD may be disposed in a pad area PDA of the non-display area NDA. In one embodiment, a wiring pad WPD_DT (hereinafter referred to as a ‘data pad’) of the data line DTL, a wiring pad WPD_RV (hereinafter referred to as a ‘reference voltage pad’) of the reference voltage line RVL, and a wiring pad WPD_ELVD (hereinafter referred to as a ‘first power pad’) of the first power line ELVDL may be disposed in the pad area PDA of the non-display area NDA. In another embodiment, the data pad WPD_DT, the reference voltage pad WPD_RV, and the first power pad WPD_ELVD may be disposed in different non-display areas NDA. As described above, the external device (e.g., ‘EXD’ in FIG. 1) may be packaged on the wiring pad WPD. The external device EXD may be packaged on the wiring pad WPD through an anisotropic conductive film, an ultrasonic bonding, or the like.

Each pixel PX on the display substrate includes a pixel driving circuit. The above-described lines may apply a driving signal to each pixel driving circuit while passing through each pixel PX or passing along its periphery. The pixel driving circuit may include a transistor and a capacitor. Various modifications may be made to the number of transistors and capacitors in each pixel driving circuit. Hereinafter, the pixel driving circuit will be described based on a 3T1C structure that includes three transistors and one capacitor, but it is not limited thereto. Various suitable pixel structures (e.g., pixel circuit structures), such as a 2T1C structure, a 7T1C structure, and a 6T1C structure, may be applied to the pixel driving circuit.

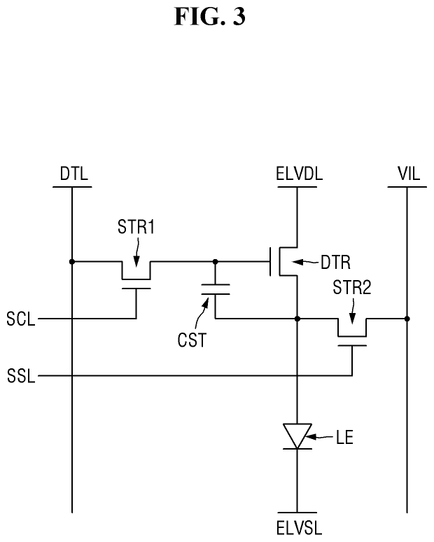

FIG. 3 is an equivalent circuit view of one pixel of a display device according to one embodiment.

Referring to FIG. 3, each pixel PX of the display device according to one embodiment includes three transistors DTR, STR1, and STR2 and one storage capacitor CST in addition to a light emitting element LE.

The light emitting element LE emits (e.g., is configured to emit) light depending on (or according to) a current supplied through the driving transistor DTR. The light emitting element LE may be implemented as an inorganic light emitting diode, an organic light emitting diode, a micro light emitting diode, a nano light emitting diode, or the like.

A first electrode (e.g., an anode electrode) of the light emitting element LE may be connected to a source electrode of the driving transistor DTR, and a second electrode (e.g., a cathode electrode) may be connected to a second power line ELVSL supplied with a second potential voltage (e.g., a low potential or power voltage) that is lower than a first potential voltage (e.g., a high potential or power voltage) of the first power line ELVDL.

The driving transistor DTR adjusts the current flowing from the first power line ELVDL, supplied with the first power voltage, to the light emitting element LE in accordance with a voltage difference between a gate electrode and the source electrode. The gate electrode of the driving transistor DTR may be connected to a first electrode of the first transistor STR1, its source electrode may be connected to the first electrode of the light emitting element LE, and its drain electrode may be connected to the first power line ELVDL, to which the first power voltage is applied.

The first transistor STR1 is turned on by a scan signal from the scan line SCL to connect the data line DTL to the gate electrode of the driving transistor DTR. A gate electrode of the first transistor STR1 may be connected to the scan line SCL, its first electrode may be connected to the gate electrode of the driving transistor DTR1, and its second electrode may be connected to the data line DTL.

The second transistor STR2 is turned on by a sensing signal from the sensing signal line SSL to connect the initialization voltage line VIL to the source electrode of the driving transistor DTR. A gate electrode of the second transistor STR2 may be connected to the sensing signal line SSL, its first electrode may be connected to the initialization voltage line VIL, and its second electrode may be connected to the source electrode of the driving transistor DTR.

In one embodiment, the first electrode of each of the first and second transistors STR1 and STR2 may be a source electrode and the second electrode thereof may be a drain electrode, but they are not limited thereto and may be vice versa.

The capacitor CST is formed between the gate electrode and the source electrode of the driving transistor DTR. The storage capacitor CST stores a differential voltage of a gate voltage and a source voltage of the driving transistor DTR.

The driving transistor DTR and the first and second transistors STR1 and STR2 may be formed of thin film transistors. In the embodiment shown in FIG. 3, the driving transistor DTR and the first and second transistors STR1 and STR2 are N-type metal oxide semiconductor field effect transistors (MOSFETs), but they are not limited thereto. In other embodiments, the driving transistor DTR and the first and second transistors STR1 and STR2 may be P-type MOSFETs, or one or more thereof may be N-type MOSFETs and one or more others thereof may be P-type MOSFETs.

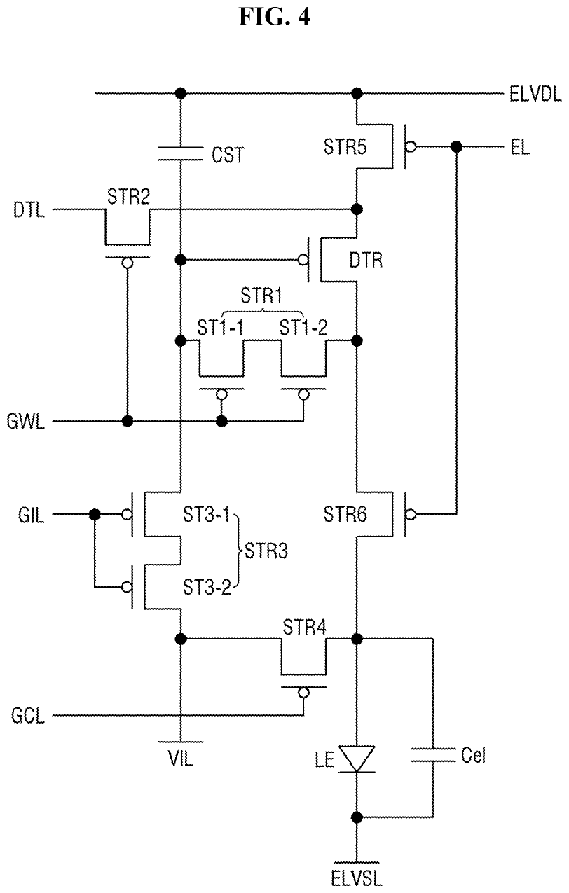

FIG. 4 is an equivalent circuit view of one pixel of a display device according to another embodiment.

Referring to FIG. 4, the first electrode of the light emitting element LE may be connected to a first electrode of a fourth transistor STR4 and a second electrode of a sixth transistor STR6, and the second electrode of the light emitting element LE may be connected to the second power line ELVSL. A parasitic capacitance Cel may be formed between the first electrode and the second electrode of the light emitting element LE.

Each pixel PX includes a driving transistor DTR, switch elements, and a capacitor CST. The switch elements include first to sixth transistors STR1, STR2, STR3, STR4, STR5, and STR6.

The driving transistor DTR includes a gate electrode, a first electrode, and a second electrode. The driving transistor DTR controls a drain-source current Ids (hereinafter, referred to as a “driving current”) flowing between the first electrode and the second electrode depending on the data voltage applied to the gate electrode thereof.

The capacitor CST is formed between the second electrode of the driving transistor DTR and the second power line ELVSL. One electrode of the capacitor CST may be connected to the second electrode of the driving transistor DTR, and the other electrode thereof may be connected to the second power line ELVSL.

When the first electrode of each of the first to sixth transistors STR1, STR2, STR3, STR4, STR5 and STR6 and the driving transistor DTR is a source electrode, the second electrode may be a drain electrode. In other embodiments, when the first electrode of each of the first to sixth transistors STR1, STR2, STR3, STR4, STR5 and STR6 and the driving transistor DTR is a drain electrode, the second electrode may be a source electrode.

An active layer of each of the first to sixth transistors STR1, STR2, STR3, STR4, STR5 and STR6 and the driving transistor DTR may be formed of any one of polysilicon, amorphous silicon, and an oxide semiconductor. When a semiconductor layer of each of the first to sixth transistors STR1, STR2, STR3, STR4, STR5 and STR6 and the driving transistor DTR is formed of polysilicon, a process of forming the semiconductor layer may be a low temperature polysilicon (LTPS) process.

Also, in FIG. 4, the first to sixth transistors STR1, STR2, STR3, STR4, STR5 and STR6 and the driving transistor DTR are described as being formed as P-type MOSFETs but are not limited thereto, and they may be formed as N-type MOSFETs.

Furthermore, the first power voltage of the first power line ELVDL, the second power voltage of the second power line ELVSL, and a third power voltage of a third power line may be set in consideration of characteristics of the driving transistor DTR, characteristics of the light emitting element LE, and the like.

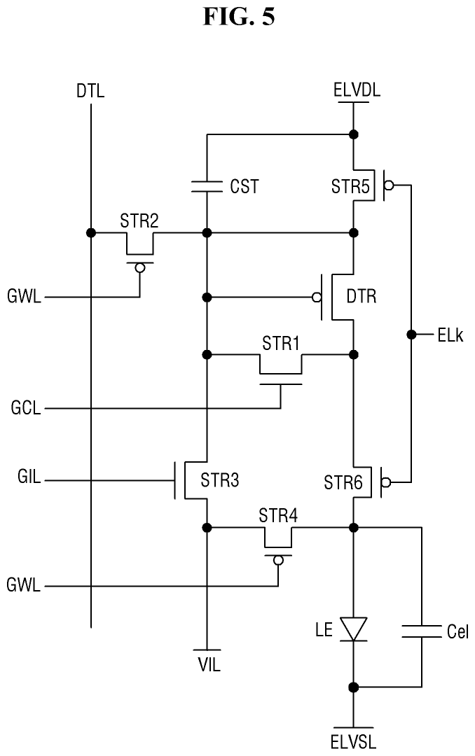

FIG. 5 is an equivalent circuit view of one pixel of a display device according to another embodiment.

The embodiment shown in FIG. 5 is different from the embodiment shown in FIG. 4 in that the driving transistor DTR, the second transistor STR2, the fourth transistor STR4, the fifth transistor STR5, and the sixth transistor ST6 are formed as P-type MOSFETs, and the first transistor STR1 and the third transistor STR3 are formed as N-type MOSFETs.

Referring to FIG. 5, the active layer of each of the driving transistor DTR, the second transistor STR2, the fourth transistor STR4, the fifth transistor STR5, and the sixth transistor STR6, which are formed as P-type MOSFETs, may be formed of polysilicon, and the active layer of each of the first transistor STR1 and the third transistor STR3, which are formed as N-type MOSFETs, may be formed of an oxide semiconductor.

The embodiment shown in FIG. 5 is also different from the embodiment shown in FIG. 4 in that the gate electrode of the second transistor STR2 and the gate electrode of the fourth transistor STR4 are connected to a write scan line GWL, and the gate electrode of the first transistor ST1 is connected to a control scan line GCL. Also, in FIG. 5, because the first transistor STR1 and the third transistor STR3 are formed as N-type MOSFETs, a scan signal of a gate high voltage may be applied to the control scan line GCL and the initialization scan line GIL. In contrast, because the second transistor STR2, the fourth transistor STR4, the fifth transistor STR5, and the sixth transistor STR6 are formed as P-type MOSFETs, a scan signal of a gate low voltage may be applied to the write scan line GWL and a light emitting line EL.

It should be noted that the equivalent circuit diagrams of a pixel are not limited to those shown in FIGS. 3 to 5. The equivalent circuit view of the pixel according to embodiments of the present disclosure may be formed in another known, suitable circuit structure that may be employed by those skilled in the art in addition to the embodiments shown in FIGS. 3 to 5.

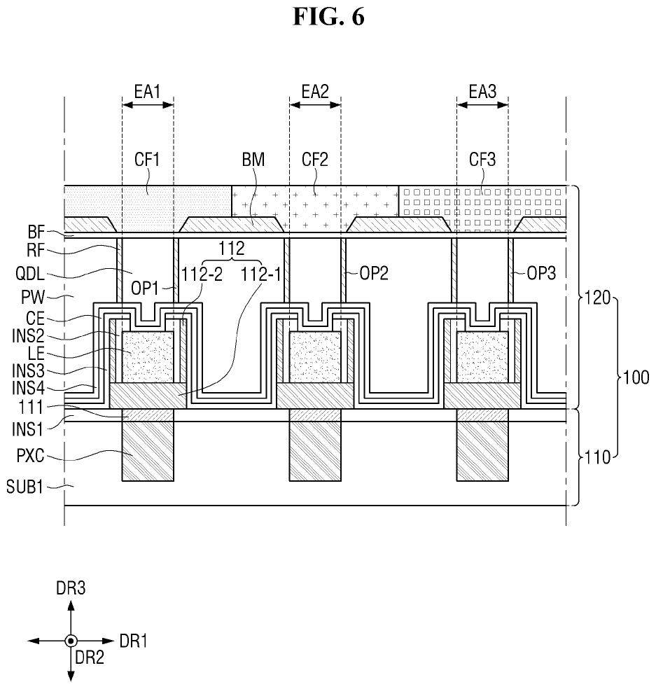

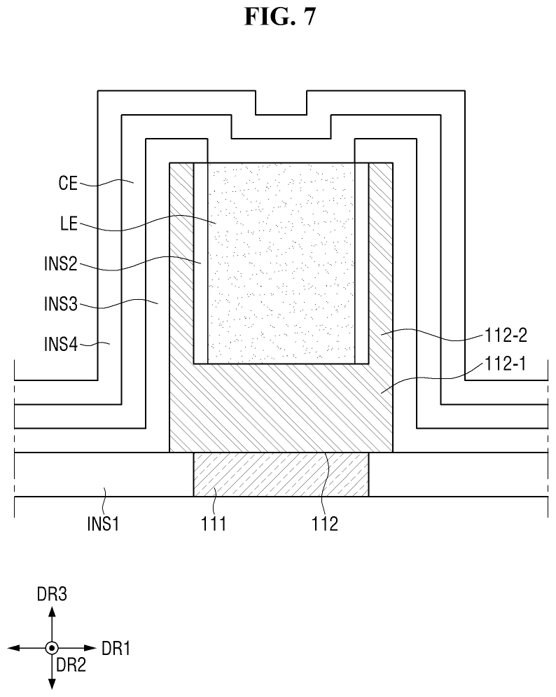

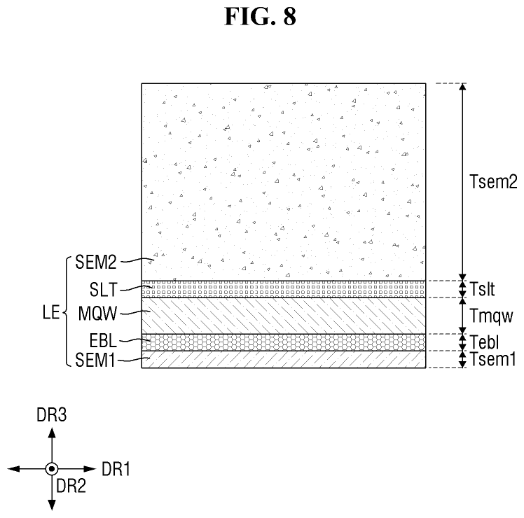

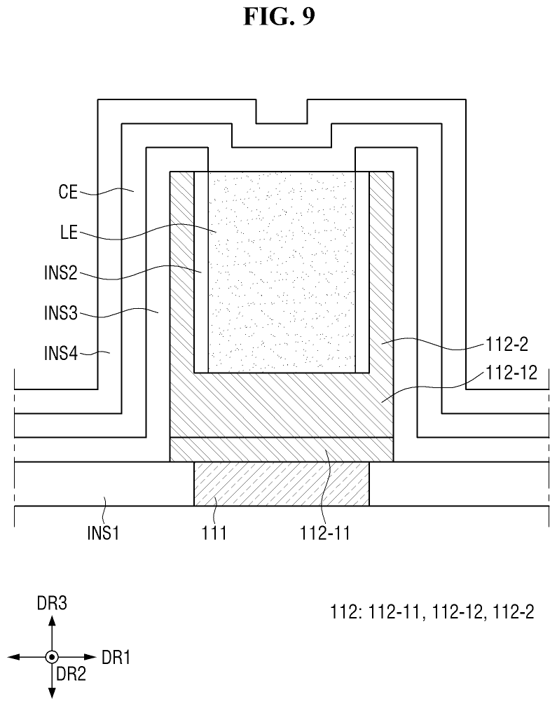

FIG. 6 is a schematic cross-sectional view illustrating a display device according to one embodiment. FIG. 7 is a cross-sectional view illustrating a pixel electrode and a light emitting element according to one embodiment. FIG. 8 is an enlarged cross-sectional view illustrating a light emitting element shown in FIG. 6 according to an embodiment, and FIG. 9 is an enlarged cross-sectional view illustrating a light emitting element shown in FIG. 6 according to another embodiment.

Referring to FIGS. 6 to 8, a display panel 100 may include a semiconductor circuit board 110 and a light emitting element layer 120.

The semiconductor circuit board 110 may include a first substrate SUB1, a plurality of pixel circuits PXC, pixel electrodes 111, a common electrode CE, and a first insulating layer INS1.

The first substrate SUB1 may be a silicon wafer substrate. The first substrate SUB1 may be made of monocrystalline silicon.

Each of the plurality of pixel circuits PXC may be disposed on the first substrate SUB1. Each of the plurality of pixel circuits PXC may include a complementary metal-oxide semiconductor (CMOS) circuit formed using a semiconductor process. Each of the plurality of pixel circuits PXC may include at least one transistor formed by a semiconductor process. In addition, each of the plurality of pixel circuits PXC may further include at least one capacitor formed by a semiconductor process.

The plurality of pixel circuits PXC may be disposed in a display area DA. Each of the plurality of pixel circuits PXC may be connected to a corresponding pixel electrode 111. For example, the plurality of pixel circuits PXC and the plurality of pixel electrodes 111 may be connected to each other in one-to-one correspondence. Each of the pixel circuits PXC may apply a pixel voltage or an anode voltage to the corresponding pixel electrode 111.

Each of the pixel electrodes 111 may be disposed on a corresponding pixel circuit PXC. Each of the pixel electrodes 111 may be an exposed electrode exposed from the pixel circuit PXC. For example, each of the pixel electrodes 111 may protrude from an upper surface of the pixel circuit PXC. Each of the pixel electrodes 111 may be integrally formed with the pixel circuit PXC. Each of the pixel electrodes 111 may be supplied with a pixel voltage or an anode voltage from the pixel circuit PXC. The pixel electrodes 111 may include copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof. In some embodiments, the pixel electrodes 111 may have a multi-layered structure in which two or more metal layer are stacked. For example, the pixel electrodes 111 may be a two-layer structure in which a copper layer is stacked on a titanium layer, but they are not limited thereto.

The first insulating layer INS1 may be disposed on the first substrate SUB1 in which the pixel electrodes 111 are not disposed. The first insulating layer INS1 is disposed between the pixel electrodes 111, and an upper surface of the first insulating layer INS1 and an upper surface of each of the pixel electrodes 111 may be connected to be flat (e.g., may form a planar surface). Therefore, the first insulating layer INS1 may be referred to as a planarization layer. The first insulating layer INS1 may be formed of an inorganic layer, such as a silicon oxide layer (SiO₂), an aluminum oxide layer (Al₂O₃), or a hafnium oxide layer (HfOₓ).

The light emitting element layer 120 may include a plurality of light emission areas EA1, EA2, and EA3 and it may be a layer that emits light (e.g., that is configured to emit light). The light emitting element layer 120 may include connection electrodes 112, light emitting elements LE, a second insulating layer INS2, a common electrode CE, a wavelength conversion layer QDL, a reflective film RF, and a plurality of color filters CF1, CF2, and CF3.

Each of the connection electrodes 112 may be disposed on a corresponding pixel electrode 111. For example, the connection electrodes 112 may be connected to the pixel electrodes 111 in one-to-one correspondence. The connection electrodes 112 may act as bonding metals to bond the pixel electrodes 111 to the light emitting elements LE during a manufacturing process. For example, the connection electrodes 112 may include gold (Au). In some embodiments, the connection electrodes 112 may include a connection portion 112-1 and a reflection portion 112-2.

The connection portion 112-1 may be disposed on the pixel electrode 111 to bond the pixel electrode 111 to the light emitting element LE, and the reflection portion 112-2 may be formed to surround (e.g., to extend around) a side of the light emitting element LE, as described below. The connection portion 112-1 may be in contact with the upper surface of the pixel electrode 111, and the reflection portion 112-2 may be in contact with an outer surface of the second insulating layer INS2, as described below. The reflection portion 112-2 reflects light moving to upper and lower sides and left and right sides, but not an upper direction, from among the light emitted from the light emitting element LE, thereby preventing the light emitted from the light emitting elements LE of the adjacent light emission areas EA1, EA2 and EA3 from mixing. The connection portion 112-1 and the reflection portion 112-2 may be integrally formed and may include the same material. For example, the connection portion 112-1 and the reflection portion 112-2 may include gold (Au).

In another embodiment, as shown in FIG. 9, the connection electrodes 112 may include a first connection portion 112-11, a second connection portion 112-12, and a reflection portion 112-2.

The first connection portion 112-11 may transfer a light emitting signal from the pixel electrode 111 to the light emitting element LE. The first connection portion 112-11 may be an Ohmic connection electrode, but is not limited thereto, and may be a Schottky connection electrode. The first connection portion 112-11 may be disposed at the lowermost end of the light emitting element LE and may be disposed to be further away from an active layer MQW than the second connection portion 112-12 is. The first connection portion 112-11 may include at least one of gold (Au), copper (Cu), tin (Sn), silver (Ag), aluminum (Al), or titanium (Ti). For example, the first connection portion 112-11 may include a 9:1 alloy, an 8:2 alloy, or a 7:3 alloy of gold and tin.

The second connection portion 112-12 may reflect light emitted from the active layer MQW of the light emitting element LE. The second connection portion 112-12 may be disposed to be adjacent to the active layer MQW of the light emitting element LE. The second connection portion 112-12 may include a metal material having conductivity and reflectance.

When each of the first connection portion 112-11 and the second connection portion 112-12 is formed of an alloy of gold and tin, gold content ratios in the first connection portion 112-11 and the second connection portion 112-12 may be different from each other. For example, the second connection portion 112-12 may have a gold content ratio that is higher than that of the first connection portion 112-11.

The second connection portion 112-12 and the reflection portion 112-2 may be integrally formed and may include the same material. For example, the second connection portion 112-12 and the reflection portion 112-2 may include gold (Au).

In the embodiment shown in FIG. 9, the connection electrode 112 has a double-layered structure, but it is not limited thereto. In some embodiments, the connection electrode 112 may be formed having a structure in which a greater number of layers are stacked.

Referring back to FIGS. 6 to 8, each of the light emitting elements LE may be disposed on the connection electrode 112. The light emitting element LE may be a vertical light emitting diode element extending in the third direction DR3. For example, a length of the light emitting element LE in the third direction DR3 may be longer than a length of the light emitting element LE in a horizontal direction. The length of the light emitting element LE in the horizontal direction indicates a length in the first direction DR1 or a length in the second direction DR2. For example, the length of the light emitting element LE in the third direction DR3 may be in a range of about 1 μm to about 5 μm.

The light emitting element LE may be a micro light emitting diode element or a nano light emitting diode. Referring to FIG. 8, the light emitting element LE includes a first semiconductor layer SEM1, an electron blocking layer EBL, an active layer MQW, a superlattice layer SLT, and a second semiconductor layer SEM2 in the third direction DR3. The first semiconductor layer SEM1, the electron blocking layer EBL, the active layer MQW, the superlattice layer SLT, and the second semiconductor layer SEM2 may be sequentially stacked in the third direction DR3.

The light emitting element LE may have a cylindrical shape, a disk shape, or a rod shape having a width greater than a height, but it is not limited thereto. The light emitting element LE may have a shape such as a rod, a wire and a tube, and a polygonal pillar shape such as a cube, a rectangular parallelepiped and a hexagonal pillar, or may have various shapes, such as a shape having an outer surface extending in one direction but partially inclined.

The first semiconductor layer SEM1 may be disposed on the connection electrode 112. The first semiconductor layer SEM1 may be doped with a first conductive type dopant, such as Mg, Zn, Ca, Se, and Ba. For example, the first semiconductor layer SEM1 may be p-GaN doped with p-type Mg. A thickness Tsem1 of the first semiconductor layer SEM1 may be in a range of about 30 nm to about 200 nm.

The electron blocking layer EBL may be disposed on the first semiconductor layer SEM1. The electron blocking layer EBL may be a layer for suppressing or preventing too many electrons from flowing to the active layer MQW. For example, the electron blocking layer EBL may be p-AlGaN doped with p-type Mg. A thickness Tebl of the electron blocking layer EBL may be in a range of about 10 nm to about 50 nm. However, in some embodiments, the electron blocking layer EBL may be omitted.

The active layer MQW may be disposed on the electron blocking layer EBL. The active layer MQW may emit light due to combination of electron-hole pairs in accordance with an electrical signal applied through the first semiconductor layer SEM1 and the second semiconductor layer SEM2. The active layer MQW may emit a first light having a main wavelength band ranging from about 450 nm to about 495 nm, that is, may emit light of a blue wavelength band, but it is not limited thereto.

The active layer MQW may include a single or multiple quantum well structure. When the active layer MQW includes a multiple quantum well structure, a plurality of well layers and a plurality of barrier layers may be alternately stacked. In such an embodiment, the well layer may be formed of, but is not limited to, InGaN, and the barrier layer may be formed of, but is not limited to, GaN or AlGaN. A thickness of the well layer may be in a range of about 1 nm to about 4 nm, and a thickness of the barrier layer may be in a range of about 3 nm to about 10 nm.

In some embodiments, the active layer MQW may have a structure in which semiconductor materials having a high band gap energy and semiconductor materials having a low band gap energy are alternately stacked and may include different group III to group V semiconductor materials depending on a wavelength band of light that is to be emitted. The light emitted from the active layer MQW may be second light (e.g., light of a green wavelength band) or third light (e.g., light of red wavelength band) and is not limited to being the first light (e.g., light of a blue wavelength band).

The superlattice layer SLT may be disposed on the active layer MQW. The superlattice layer SLT may be a layer for mitigating stress between the second semiconductor layer SEM2 and the active layer MQW. For example, the superlattice layer SLT may be formed of InGaN or GaN. A thickness Tslt of the superlattice layer SLT may be in a range of about 50 nm to about 200 nm. However, in some embodiments, the superlattice layer SLT may be omitted.

The second semiconductor layer SEM2 may be disposed on the superlattice layer SLT. The second semiconductor layer SEM2 may be doped with a second conductive type dopant, such as Si, Ge, and Sn. For example, the second semiconductor layer SEM2 may be n-GaN doped with n-type Si. A thickness Tsem2 of the second semiconductor layer SEM2 may be in a range of about 500 nm to about 1 μm.

The second insulating layer INS2 may be disposed on sides of each of the light emitting elements LE. The second insulating layer INS2 is not disposed on an upper surface of each of the light emitting elements LE. The second insulating layer INS2 may be formed of an inorganic layer, such as a silicon oxide layer (SiO₂), an aluminum oxide layer (Al₂O₃), or a hafnium oxide layer (HfO_{X}), but is not limited thereto.

A third insulating layer INS3 may be disposed on sides of each of the connection electrodes 112. The third insulating layer INS3 may be disposed on an upper surface of each of the connection electrodes 112. The third insulating layer INS3 is disposed along an upper surface and sides of the reflection portion 112-2 and sides of the connection portion 112-1. For example, the third insulating layer INS3 may be disposed to surround the sides and the upper surface of the connection electrode 112. The third insulating layer INS3 may be disposed on the first insulating layer INS1 at where the connection electrode 112 is not disposed. The third insulating layer INS3 may not be disposed on the upper surface of each of the light emitting elements LE. The third insulating layer INS3 may be formed of an inorganic layer, such as a silicon oxide layer (SiO₂), an aluminum oxide layer (Al₂O₃), or a hafnium oxide layer (HfO_{X}), but is not limited thereto.

The common electrode CE may include a material having low resistance as it is entirely disposed on the first substrate SUB1 to apply a common voltage. The common electrode CE may be disposed on the upper surface of each of the light emitting elements LE and an upper surface of the third insulating layer INS3. The common electrode CE may be disposed to completely cover each of the light emitting elements LE. In addition, the common electrode CE may be formed to have a thin thickness (e.g., may be relatively thin) to facilitate transmission of light. The common electrode CE may include a transparent conductive material. For example, the common electrode CE may include a transparent conductive oxide (TCO), such as indium tin oxide (ITO) or indium zinc oxide (IZO). The thickness of the common electrode CE may be in a range of about 10 Å to about 200 Å but is not limited thereto.

A fourth insulating layer INS4 may be disposed on the common electrode CE. For example, the fourth insulating layer INS4 is disposed between the wavelength conversion layer QDL, which will be described later, and the common electrode CE. The fourth insulating layer INS4 may be formed of an inorganic layer, such as a silicon oxide layer (SiO₂), an aluminum oxide layer (Al₂O₃), or a hafnium oxide layer (HfOₓ), but is not limited thereto.

The wavelength conversion layer QDL may be disposed on the fourth insulating layer INS4 in each of the first light emission areas EA1 and the third light emission areas EA3. The wavelength conversion layer QDL may overlap the light emitting element LE in the third direction DR3 in each of the first light emission areas EA1, the second light emission areas EA2, and the third light emission areas EA3.

The wavelength conversion layer QDL may include first wavelength conversion particles. The first wavelength conversion particles may convert the first light emitted from the light emitting element LE into the fourth light. For example, the first wavelength conversion particles may convert light of a blue wavelength band into light of a yellow wavelength band. The first wavelength conversion particles may be quantum dots (QD), quantum rods, fluorescent materials, or phosphorescent materials. The quantum dots may include group IV nanocrystal, group II-VI compound nanocrystal, group III-V compound nanocrystal, group IV-VI nanocrystal, or their combination.

The quantum dots may include a core and a shell that over-coats the core. For example, the core may be, but not limited to, at least one of CdS, CdSe, CdTe, ZnS, ZnSe, ZnTe, GaN, GaP, GaAs, GaSb, AlN, AlP, AlAs, AlSb, InP, InAs, InSb, SiC, Ca, Se, In, P, Fe, Pt, Ni, Co, Al, Ag, Au, Cu, FePt, Fe₂O₃, Fe₃O₄, Si, or Ge. The shell may include, but is not limited to, at least one of ZnS, ZnSe, ZnTe, CdS, CdSe, CdTe, HgS, HgSe, HgTe, AlN, AlP, AlAs, AlSb, GaN, GaP, GaAs, GaSb, GaSe, InN, InP, InAs, InSb, TIN, TIP, TIAs, TISb, PbS, PbSe, or PbTe.

The wavelength conversion layer QDL may further include a scatterer for scattering the light of the light emitting element LE in random directions. In such an embodiment, the scatterer may include metal oxide particles or organic particles. For example, the metal oxide may be titanium oxide (TiO₂), zirconium oxide (ZrO₂), silicon dioxide (SiO₂), aluminum oxide (Al₂O₃), indium oxide (In₂O₃), zinc oxide (ZnO), or tin oxide (SnO₂). In addition, the organic particles may include an acrylic resin or a urethane-based resin. A diameter of the scatterer may be in a range of several nanometers to several tens of nanometers.

Partition walls PW may be disposed on the common electrode CE in the display area DPA and may define a plurality of light emission areas EA1, EA2, and EA3 and a non-light emission area. The partition wall PW may be disposed to extend in the first direction DR1 and the second direction DR2 and may be formed in a lattice-shaped pattern throughout the display area DPA. Further, the partition wall PW may not overlap the plurality of light emission areas EA1, EA2 and EA3 and may overlap the non-light emission area NEA.

The partition wall PW may have a plurality of openings OP1, OP2, and OP3 that expose the common electrode CE therebelow. The plurality of openings OP1, OP2, and OP3 may include a first opening OP1 that overlaps the first light emission area EA1, a second opening OP2 that overlaps the second light emission area EA2, and a third opening OP3 that overlaps the third light emission area EA3. In the illustrated embodiment, the plurality of openings OP1, OP2, and OP3 may correspond to the plurality of light emission areas EA1, EA2, and EA3. For example, the first opening OP1 may correspond to the first light emission area EA1, the second opening OP2 may correspond to the second light emission area EA2, and the third opening OP3 may correspond to the third light emission area EA3.

The partition wall PW may provide (or may form) a space for forming the wavelength conversion layer QDL. To this end, the partition wall PW may have a thickness (e.g., a predetermined thickness); for example, the thickness of the partition wall PW may be in a range of about 1 μm to about 10 μm. The partition wall PW may include an organic insulating material. The organic insulating material may include, for example, an epoxy-based resin, an acrylic resin, a cardo-based resin, or an imide-based resin.

The reflective film RF may be disposed on sides of the partition wall PW and the wavelength conversion layer QDL and may be positioned between the partition wall and the wavelength conversion layer QDL. The reflective film RF overlaps the non-light emission area. The reflective film RF reflects the light moving toward upper and lower sides and left and right sides, but not moving in the upper direction, from among the light emitted from the light emitting element LE. The reflective film RF may include a metal material having high reflectance, such as aluminum (Al). A thickness of the reflective film RF may be about 0.1 μm.

In one embodiment, the reflective film RF may be arranged in a line with (e.g., aligned with) the reflection portion 112-2 of the connection electrode 112 in the third direction DR3 but is not limited thereto.

The plurality of color filters CF1, CF2, and CF3 may be disposed on the partition wall PW and the wavelength conversion layer QDL. The plurality of color filters CF1, CF2, and CF3 may overlap the plurality of pixel circuits PXC and the wavelength conversion layers QDL. The plurality of color filters CF1, CF2 and CF3 may include a first color filter CF1, a second color filter CF2, and a third color filter CF3.

The plurality of color filters CF1, CF2, and CF3 may include first color filters CF1, second color filters CF2, and third color filters CF3.

Each of the first color filters CF1 may be disposed on the wavelength conversion layer QDL in the first light emission area EA1. Each of the first color filters CF1 may transmit the first light and may absorb or block the second light and the third light. For example, each of the first color filters CF1 may transmit light of the blue wavelength band and may absorb or block light of the green and red wavelength bands. Therefore, each of the first color filters CF1 may transmit the first light emitted from the light emitting element LE. That is, the first light emitted from the light emitting element LE in the first light emission area EA1 is not converted by a separate wavelength conversion layer and may transmit (e.g., may pass through) the first color filter CF1 through a light transmitting layer. Therefore, each of the first light emission areas EA1 may emit the first light.

Each of the second color filters CF2 may be disposed on the wavelength conversion layer QDL in the second light emission area EA2. Each of the second color filters CF2 may transmit the second light and may absorb or block the first light and the third light. For example, each of the second color filters CF2 may transmit the light of the green wavelength band and may absorb or block the light of the blue and red wavelength bands. Therefore, each of the second color filters CF2 may absorb or block the first light that is not converted by the wavelength conversion layer QDL from among the first light emitted from the light emitting element LE. In addition, each of the second color filters CF2 may transmit the second light corresponding to the green wavelength band from among the fourth light converted by the wavelength conversion layer QDL and may absorb or block the third light corresponding to the blue wavelength band. Therefore, each of the second light emission areas EA2 may emit the second light.

Each of the third color filters CF3 may be disposed on the wavelength conversion layer QDL in the third light emission area EA3. Each of the third color filters CF3 may transmit the third light and may absorb or block the first light and the second light. For example, each of the third color filters CF3 may transmit the light of the red wavelength band and may absorb or block the light of the blue and green wavelength bands. Therefore, each of the third color filters CF3 may absorb or block the first light that is not converted by the wavelength conversion layer QDL from among the first light emitted from the light emitting element LE. In addition, each of the third color filters CF3 may transmit the third light corresponding to the red wavelength band from among the fourth light converted by the wavelength conversion layer QDL and may absorb or block the second light corresponding to the green wavelength band. Therefore, each of the third light emission areas EA3 may emit the third light. In another embodiment, a light transmitting layer may be formed in place of the wavelength conversion layer QDL in any one of the first light emission area EA1, the second light emission area EA2, and the third light emission area EA3. The light transmitting layer may be disposed on the common electrode CE in each of the first light emission areas EA1. The light transmitting layer may overlap the light emitting element LE in the third direction DR3 in each of the first light emission areas EA1. The light transmitting layer may include a light-transmissive organic material. For example, the light transmitting layer may include an epoxy-based resin, an acrylic resin, a cardo-based resin, or an imide-based resin.

A black matrix may be disposed among (e.g., between) the plurality of color filters CF1, CF2, and CF3. For example, the black matrix may be disposed between the first color filter CF1 and the second color filter CF2, between the second color filter CF2 and the third color filter CF3, and between the first color filter CF1 and the third color filter CF3. The black matrix may include an inorganic black pigment or an organic black pigment, such as carbon black.

A planar area of each of the plurality of color filters CF1, CF2, and CF3 may be larger than a planar area of each of the plurality of light emission areas EA1, EA2, and EA3. For example, the first color filter CF1 may be larger than the planar area of the first light emission area EA1. The second color filter CF2 may be larger than the planar area of the second light emission area EA2. The third color filter CF3 may be larger than the planar area of the third light emission area EA3. However, the present disclosure is not limited thereto, and the planar area of each of the plurality of color filters CF1, CF2, and CF3 may be the same as the planar area of each of the plurality of light emission areas EA1, EA2, and EA3.

A light blocking member BM may be disposed on the partition wall PW. The light blocking member BM may overlap the non-light emission area NEA to block the transmission of light. The light blocking member BM may be disposed substantially in a planar lattice shape similar to the partition wall PW. The light blocking member BM may be disposed to overlap the partition wall PW and may not overlap (e.g., may be offset from) the light emission areas EA1, EA2, and EA3.

In one embodiment, the light blocking member BM may include an organic light blocking material and may be formed through coating and exposure processes of an organic light blocking material. The light blocking member BM may include a dye or a pigment, which has light blocking property, and may be a black matrix. At least a portion of the light blocking member BM may overlap the adjacent color filters CF1, CF2, and CF3, and the color filters CF1, CF2 and CF3 may be disposed on at least a portion of the light blocking member BM.

When the light blocking member BM is disposed on the partition wall PW, at least a portion of external light is absorbed by the light blocking member BM. Therefore, color distortion caused by reflection of the external light may be attenuated. In addition, the light blocking member BM may prevent a color mixture due to light leakage between adjacent light emission areas from occurring, thereby improving a color reproduction rate.

A protective layer BF may be disposed below the plurality of color filters CF1, CF2, and CF3 and the light blocking member BM. The protective layer BF may be disposed on the partition wall PW and the wavelength conversion layer QDL. One surface of the protective layer BF, for example, an upper surface of the protective layer BF, may be in contact with a lower surface of each of the plurality of color filters CF1, CF2, and CF3 and the light blocking member BM. In addition, the other surface facing one surface of the protective layer BF, for example, a lower surface of the protective layer BF, may be in contact with an upper surface of each of the partition wall PW and the wavelength conversion layer QDL. The protective layer BF may include an inorganic insulating material. For example, the protective layer BF may include, but is not limited to, silicon oxide (SiOₓ), silicon nitride (SiNₓ), silicon oxynitride (SiOₓN_{y}), aluminum oxide (AlₓO_{y}), aluminum nitride (AlN), and the like. The protective layer BF may have a thickness (e.g., a predetermined thickness), for example, in a range of about 0.01 μm to about 1 μm but is not limited thereto.

Hereinafter, a manufacturing process of the display device 10 according to one embodiment will be described with reference to the other drawings.

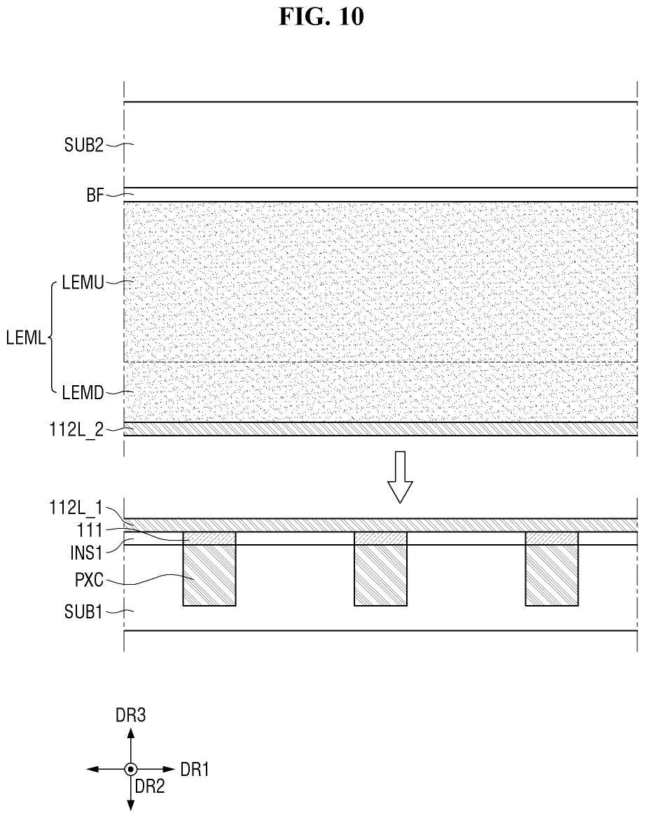

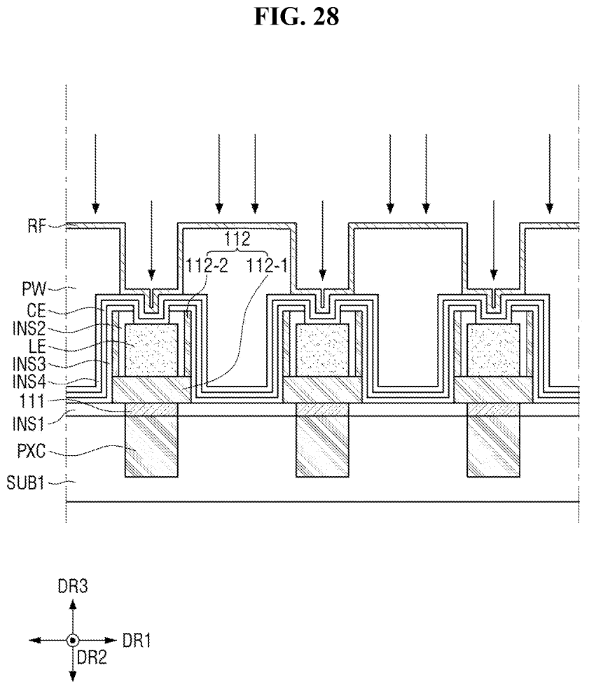

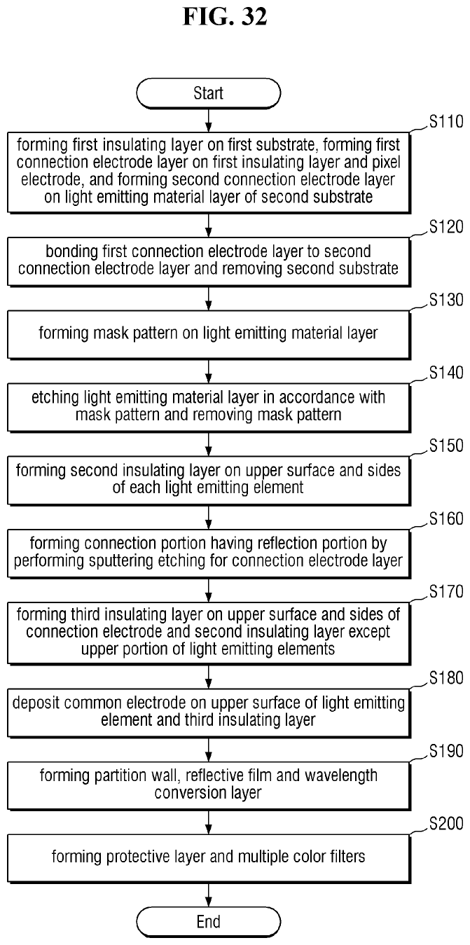

FIGS. 10 to 31 are cross-sectional views illustrating steps of a method for manufacturing a display device according to one embodiment, and FIG. 32 is a flow chart describing the steps of the method for manufacturing a display device shown in FIGS. 10 to 31.

As shown in FIG. 10, a first insulating layer INS1 is formed on a first substrate SUB1, a first connection electrode layer 112L_1 is formed on the first insulating layer INS1 and the pixel electrode 111, and a second connection electrode layer 112L_2 is formed on a light emitting material layer LEML of a second substrate SUB2 (S110 of FIG. 32).

For example, the first insulating layer INS1 is formed on the first substrate SUB1 at where the pixel electrodes 111 are not disposed (e.g., between the pixel electrodes 111). An upper surface of the first insulating layer INS1 and an upper surface of each of the pixel electrodes 111 may be connected to be flat (or planar). That is, a height difference between an upper surface of the first substrate SUB1 and the upper surface of the pixel electrode 111 filled (or avoided) by the first insulating layer INS1. The first insulating layer INS1 may be formed of an inorganic layer, such as a silicon oxide layer (SiO₂), an aluminum oxide layer (Al₂O₃), or a hafnium oxide layer (HfOₓ).

Then, the first connection electrode layer 112L_1 is deposited on the pixel electrodes 111 and the first insulating layer INS1. The first connection electrode layer 112L_1 may include gold (Au).

In addition, a buffer film BF may be formed on one surface of the second substrate SUB2. The second substrate SUB2 may be a silicon substrate or a sapphire substrate. The buffer film BF may be formed of an inorganic layer, such as a silicon oxide layer (SiO₂), an aluminum oxide layer (Al₂O₃), or a hafnium oxide layer (HfOₓ).

A light emitting material layer LEML may be disposed on the buffer film BF. The light emitting material layer LEML may include a first semiconductor material layer LEMD and a second semiconductor material layer LEMU. The second semiconductor material layer LEMU may be disposed on the buffer film BF, and the first semiconductor material layer LEMD may be disposed on the second semiconductor material layer LEMU. A thickness of the second semiconductor material layer LEMU may be greater than that of the first semiconductor material layer LEMD.

The first semiconductor material layer LEMD may include a first semiconductor layer SEM1, an electron blocking layer EBL, an active layer MQW, a superlattice layer SLT, and a second semiconductor layer SEM2, as shown in, for example, FIG. 7. The second semiconductor material layer LEMU may be a semiconductor layer that is not doped with a dopant, that is, it may be an undoped semiconductor layer. For example, the second semiconductor material layer LEMU may be an undoped-GaN that is not doped with a dopant.

The second connection electrode layer 112L_2 may be deposited on the first semiconductor material layer LEMD. The second connection electrode layer 112L_2 may include gold (Au).

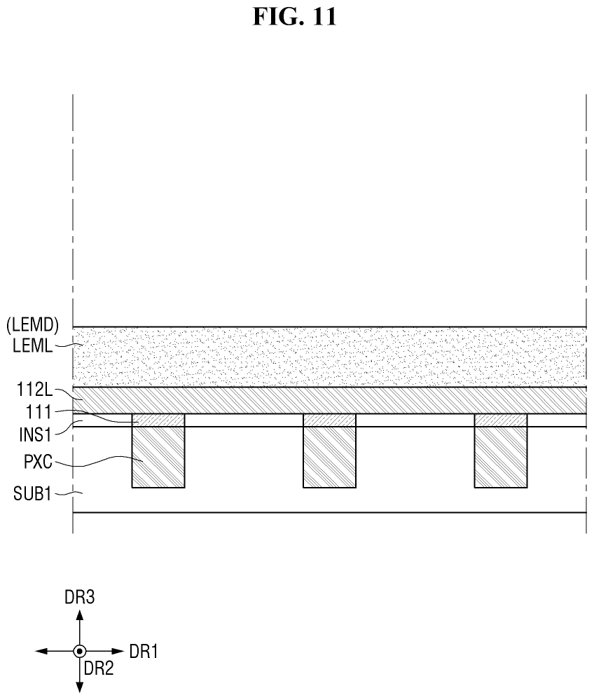

As shown in FIG. 11, the first connection electrode layer 112L_1 and the second connection electrode layer 112L_2 are bonded to each other, and the second substrate SUB2 is removed (S120 of FIG. 32).

For example, the first connection electrode layer 112L_1 of the first substrate SUB1 and the second connection electrode layer 112L_2 of the second substrate SUB2 are brought into contact with each other. Then, the first connection electrode layer 112L1 and the second connection electrode layer 112L2 are melt bonded at a temperature (e.g., at a predetermined temperature) to form one connection electrode layer 112L. That is, the connection electrode layer 112L is disposed between the pixel electrodes 111 of the first substrate SUB1 and the light emitting material layer LEML of the second substrate SUB2 to act as a bonding metal layer for bonding the pixel electrodes 111 of the first substrate SUB1 to the light emitting material layer LEML of the second substrate SUB2.

Then, the second substrate SUB2 and the buffer film BF may be removed through a polishing process, such as a chemical mechanical polishing (CMP) process, and/or an etching process. In addition, the second semiconductor material layer LEMU of the light emitting material layer LEML may be removed through the polishing process, such as the CMP process.

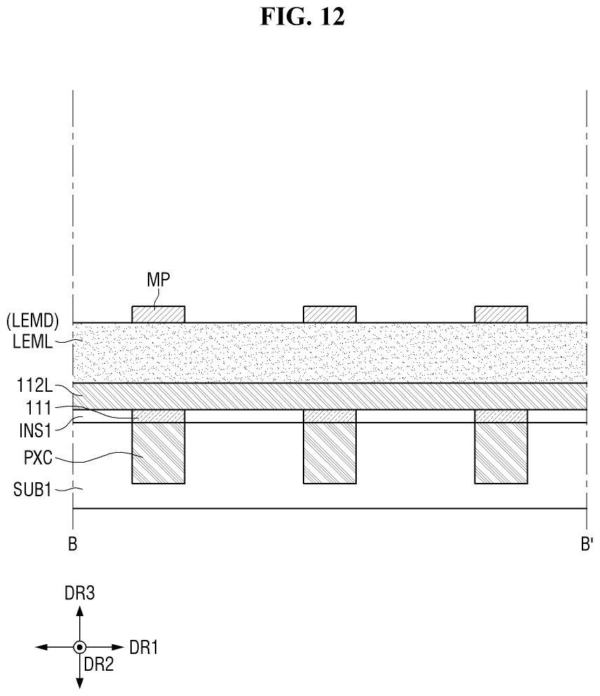

As shown in FIG. 12, a mask pattern MP is formed on the light emitting material layer LEML (S130 of FIG. 32).

The mask pattern MP is formed on the upper surface of the light emitting material layer LEML. The upper surface of the light emitting material layer LEML may be an upper surface of the first light emitting material layer LEMD, which is exposed by removing the second substrate SUB2, the buffer film BF and the second light emitting material layer LEMU. The mask pattern MP may be disposed in an area where the light emitting element LE is to be formed. As a result, the mask pattern MP may overlap the pixel electrode 111 in the third direction DR3. The mask pattern MP may include a conductive material, such as nickel (Ni). A thickness of the mask pattern MP may be in a range of about 0.01 μm to about 1 μm.

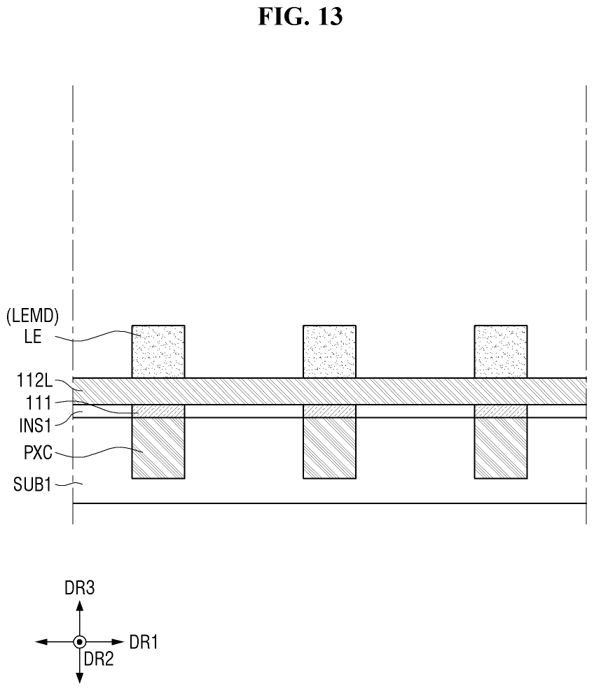

As shown in FIG. 13, the light emitting material layer LEML is etched in accordance with the mask pattern MP, and then, the mask pattern MP is removed (S140 of FIG. 32).

For example, the mask pattern MP may not be etched by an etching material for etching the light emitting material layer LEML. For this reason, the light emitting material layer LEML of the area where the mask pattern MP is disposed may not be etched. Therefore, the light emitting element LE may be formed on the upper surface of each of the pixel electrodes 111. The mask pattern MP is then removed.

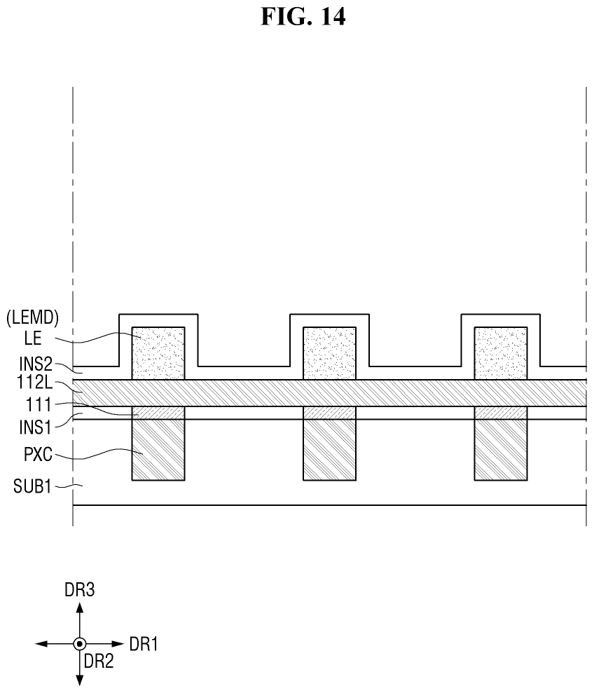

As shown in FIGS. 14 to 16, a second insulating layer INS2 is formed on the upper surface and sides of each of the light emitting elements LE (S150 of FIG. 32).

For example, as shown in FIG. 14, the second insulating layer INS2 is deposited on the upper surface and sides of each of the light emitting elements LE and the connection electrode layer 112L.

The second insulating layer INS2 may be disposed on the upper surface and sides of each of the light emitting elements LE and the connection electrodes 112 in which the light emitting element LE is not disposed. The second insulating layer INS2 may be formed of an inorganic layer, such as a silicon oxide layer (SiO₂), an aluminum oxide layer (Al₂O₃), or a hafnium oxide layer (HfOₓ).

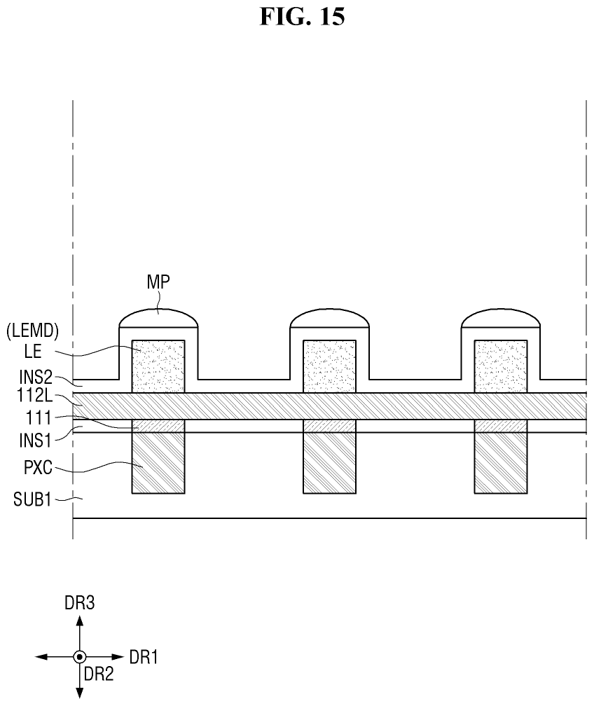

As shown in FIG. 15, the mask pattern MP is formed on the second insulating layer INS2.

The mask pattern MP may overlap the pixel electrode 111 in the third direction DR3. The mask pattern MP may include a conductive material, such as nickel (Ni). A thickness of the mask pattern MP may be in a range of about 0.01 μm to about 1 μm.

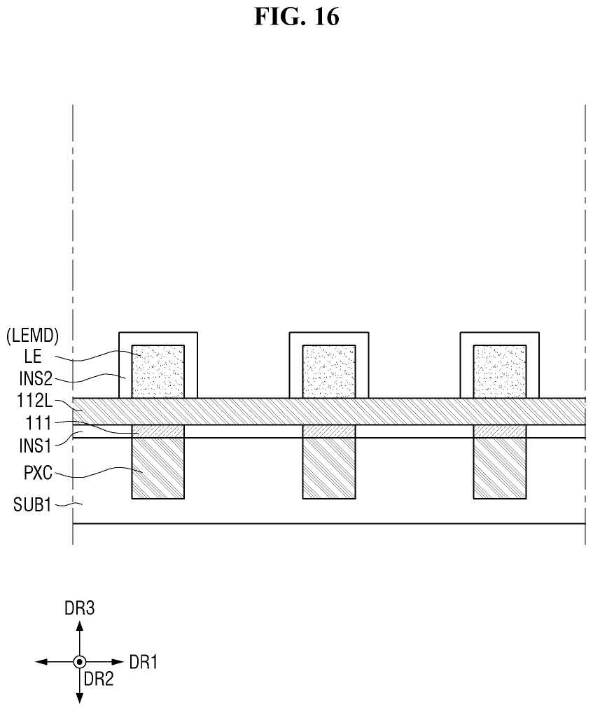

As shown in FIGS. 15 and 16, the second insulating layer INS2, on which the mask pattern MP is not disposed, and the connection electrode layer 112L are etched to form the light emitting elements LE, and the mask pattern MP is then removed.

The mask pattern MP may not be etched by an etching material for etching the light emitting material layer LEML. For this reason, the light emitting material layer LEML in the area at where the mask pattern MP is disposed and the connection electrode layer 112L may not be etched. Therefore, the second insulating layer INS2 may be formed on the upper surface and sides of each of the light emitting elements LE. Also, the connection electrode layer 112L on which the light emitting element LE is not disposed may be exposed. The mask pattern MP is then removed.

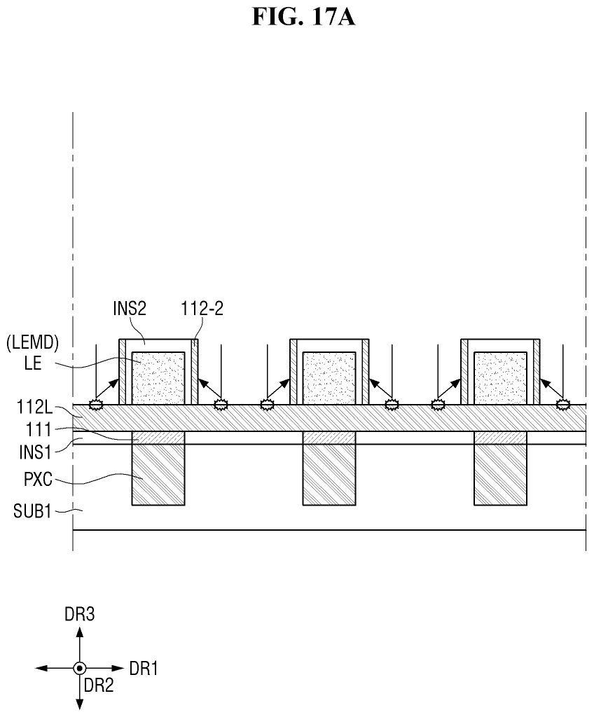

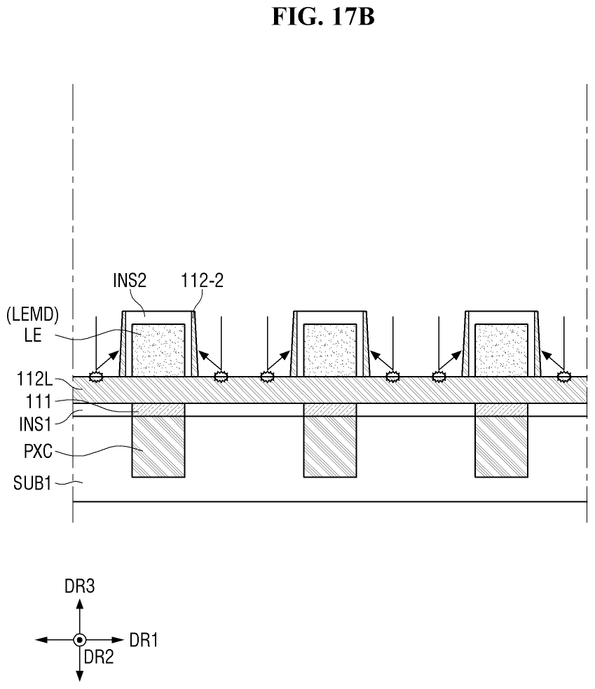

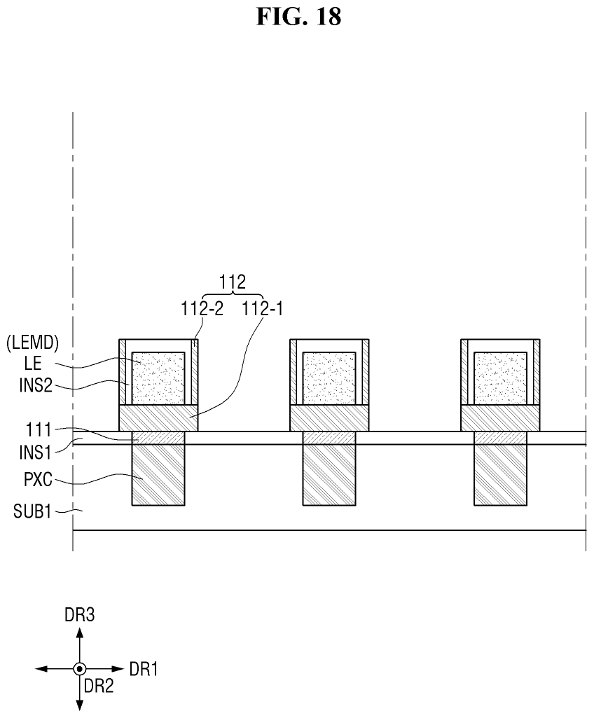

As shown in FIGS. 17A, 17B, and 18, the connection electrode layer 112L is dry-etched at a low temperature without a separate mask to form a connection electrode 112 having a reflection portion 112-2 (S160 of FIG. 32).

The dry etching may be performed by using sputtering etching, reactive radical etching, reactive ion etching, and Cl₂ gas-based inductively coupled plasma reactive ion etching (ICP-RIE) equipment. In one embodiment, the sputtering etching method is used. The sputtering etching is performed by accelerating a gas, such as argon (Ar), at a relatively low temperature, allowing the gas to collide with a target, and ejecting atoms. The sputtering etching may be performed at a temperature in a range of about 20° C. to about 100° C., and in one embodiment, the sputtering etching may be performed at about 80° C. A connection portion 112-1 of the connection electrode 112 is formed by performing the sputtering etching for the connection electrode layer 112L at a low temperature. At this time, non-volatile materials from the connection electrode layer 112L are adhered to a sidewall of the second insulating layer INS2 to form a reflection portion 112-2, as shown in, for example, FIG. 7. The reflection portion 112-2 may be integrally formed with the connection portion 112-1. In FIG. 17A, the reflection portion 112-2 is illustrated as being formed to have the same thickness as that of the connection portion 112-1 as its distance from the connection portion 112-1 increases, but the present disclosure is not limited thereto. For example, as shown in FIG. 17B, the reflection portion 112-2 may be formed to be thinner as its distance from the connection portion 112-1 increases.

In one embodiment, because the reflection portion 112-2 of the connection electrode 112 is formed by re-arrangement (e.g., rearrangement of atoms and/or materials) occurring during sputtering etching, the light emitting element may not be damaged when compared with etching using a mask or the like.

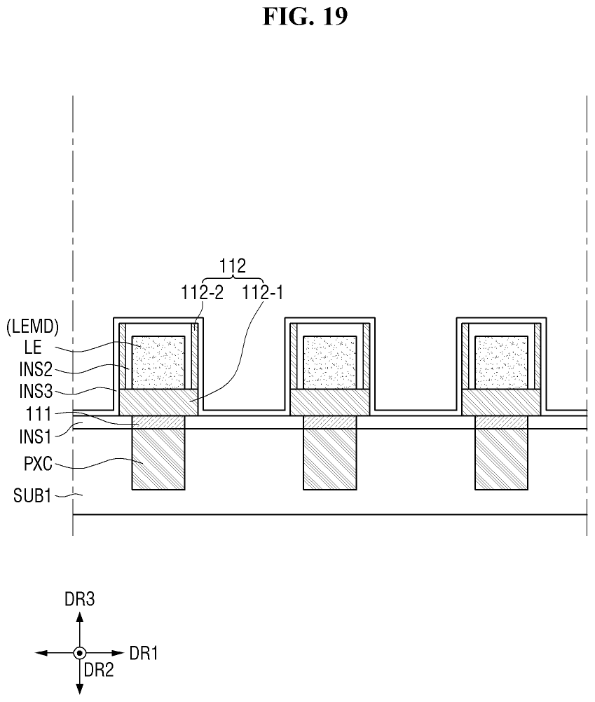

As shown in FIG. 19 to FIG. 21, a third insulating layer INS3 is formed on an upper portion and sides of the connection electrode 112 and the second insulating layer INS2 except at the upper portion of the light emitting element LE (S170 of FIG. 32).

For example, as shown in FIG. 19, a third insulating layer INS3 is deposited to cover an entire surface of the first substrate SUB1 on which the light emitting element LE is disposed. The third insulating layer INS3 is formed on the upper surface of each of the light emitting elements LE, the sides of the connection electrode 112, an upper surface and sides of the reflection portion 112-2, and the second insulating layer INS2.

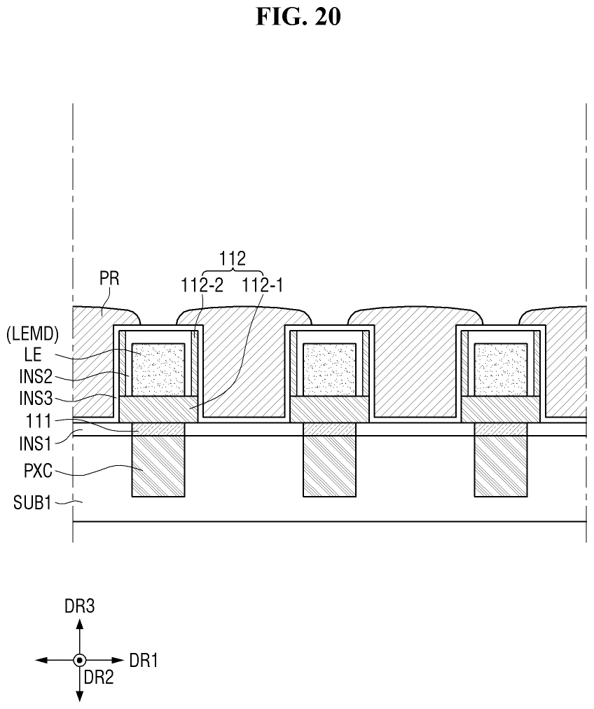

As shown in FIG. 20, a photoresist pattern PR is formed on the third insulating layer INS3. In one embodiment, the photoresist pattern PR may be a positive photoresist pattern.

The photoresist pattern PR is disposed so as not to overlap (e.g., to be offset from or outside of) the light emission area. The photoresist pattern PR may be disposed to overlap the non-light emission area.

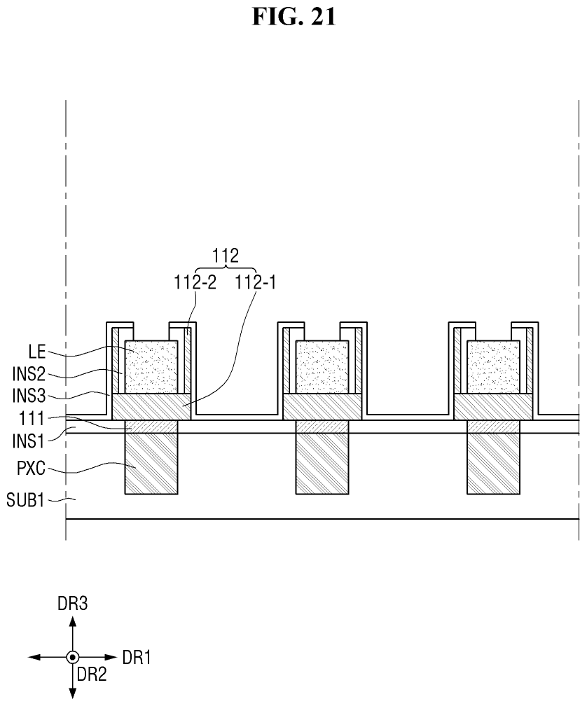

Then, the third insulating layer INS3 and the second insulating layer INS2, which are disposed on the upper surface of the light emitting element LE of each of the light emission areas that are not covered by the photoresist pattern PR, are removed as shown in FIG. 21. For example, the third insulating layer INS3 and the second insulating layer INS2 at the area overlapping the light emission area may be etched to expose the upper area of the light emitting element LE. The photoresist pattern PR is then removed.

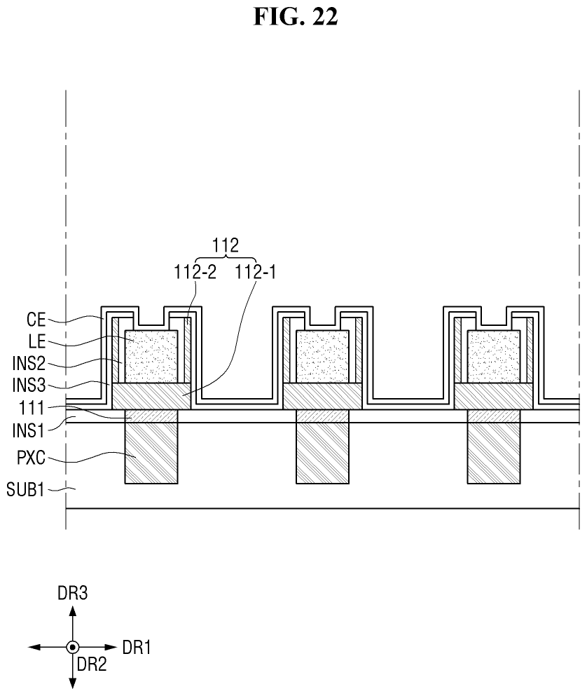

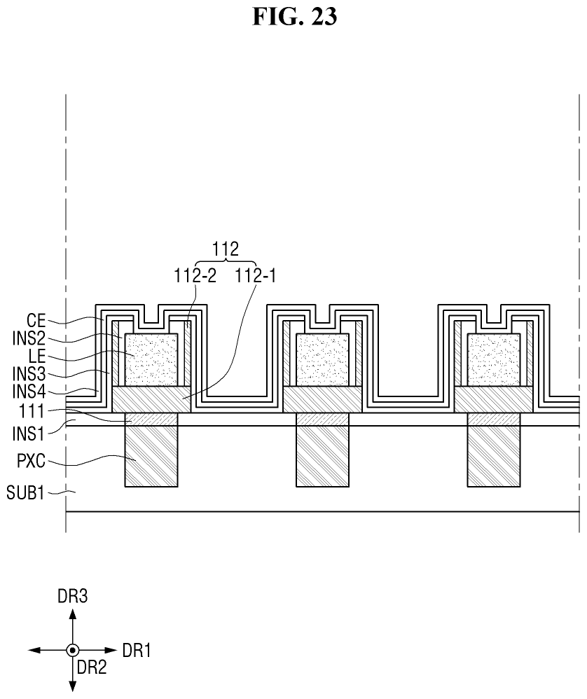

A common electrode CE is deposited on the upper surface of the light emitting element LE, which is not covered by the third insulating layer INS3, and the third insulating layer INS3 as shown in FIG. 22, and a fourth insulating layer INS4 is formed on the common electrode CE as shown in FIG. 23 (S180 in FIG. 32).

The common electrode CE may include a transparent conductive oxide (TCO), such as indium tin oxide (ITO) or indium zinc oxide (IZO).

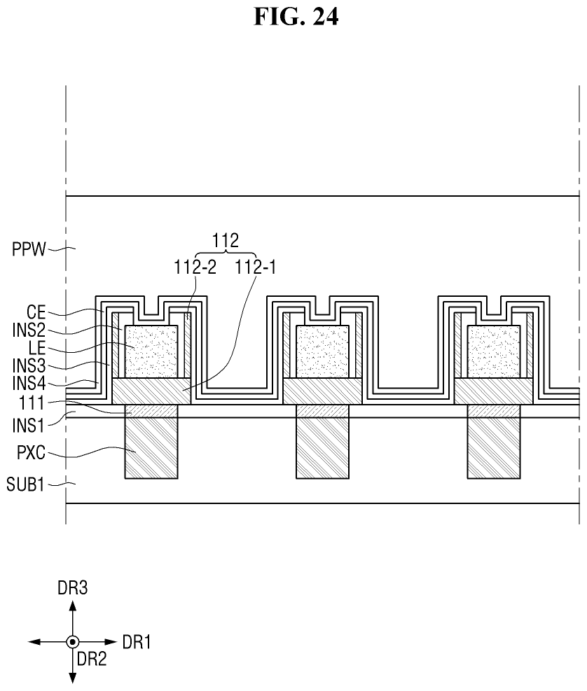

As shown in FIGS. 24 to 29, a partition wall PW, a reflective film RF, and a wavelength conversion layer QDL are formed (S190 of FIG. 32).

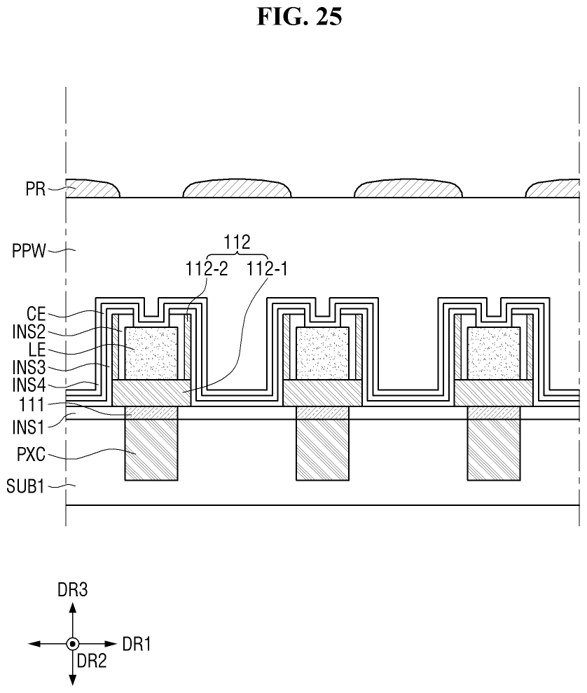

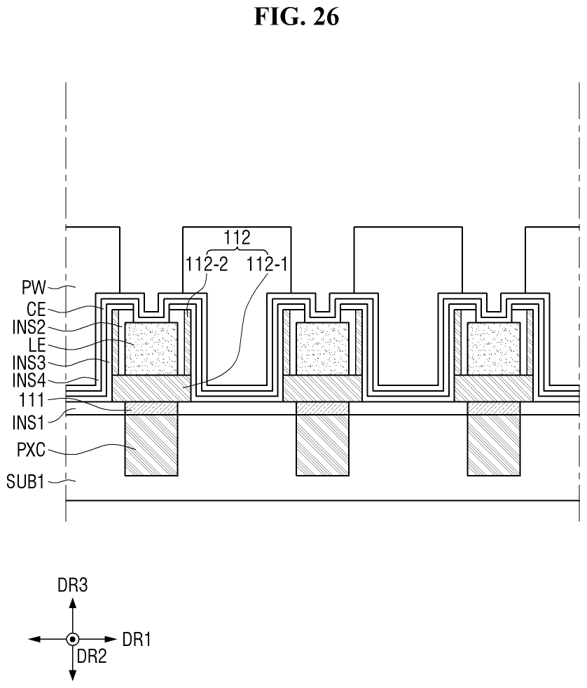

For example, as shown in FIG. 24, an organic material PPW is coated on the fourth insulating layer INS4. Then, a mask pattern PR is disposed in the non-light emission area as shown in FIG. 25. As shown in FIG. 26, the organic material PPW is patterned to form the partition wall PW. An opening may be formed in the light emission area by the mask pattern PR disposed in the non-light emission area. The mask pattern PR is then removed.

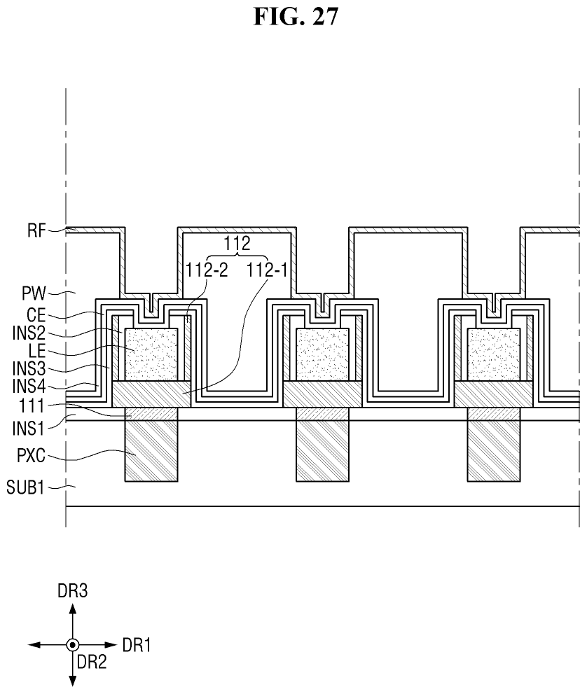

As shown in FIG. 27, the reflective film RF is deposited to cover the first substrate SUB1 on which the partition wall PW is formed.

Then, a voltage difference (e.g., a large or relatively large voltage difference) is formed in the third direction DR3 without a separate mask, and the reflective film is etched by the etching material. The etching material may etch the reflective film RF while moving in the third direction DR3, that is, from the top to the bottom under the control of the voltage (e.g., the voltage difference). For this reason, the reflective film RF disposed on a horizontal plane defined by the first direction DR1 and the second direction DR2 is removed, while the reflective film RF disposed on a vertical plane defined by the third direction DR3 may not be removed. Therefore, the reflective film RF disposed on the upper surface of the fourth insulating layer INS4 in each of the first light emission areas EA1, the second light emission areas EA2, and the third light emission areas EA3 and the partition wall PW may be removed. However, the reflective film RF disposed on sides of the partition wall PW may not be removed. Therefore, the reflective film RF may be disposed on the sides of the partition wall PW in each of the first light emission areas EA1, the second light emission areas EA2 and the third light emission areas EA3.

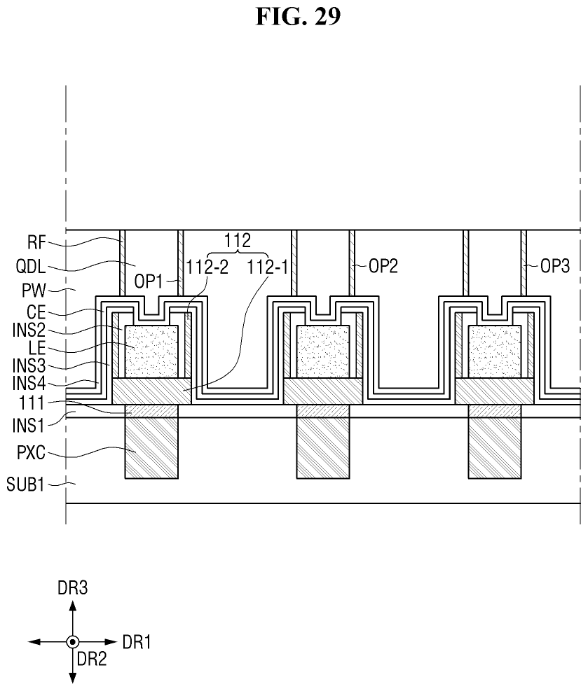

As shown in FIG. 29, a wavelength conversion layer QDL is formed in the openings formed between the partition walls PW. The wavelength conversion layer QDL may be formed to fill the plurality of openings. The wavelength conversion layer QDL may be formed by a solution process, such as inkjet printing, imprinting, etc., for a solution in which first wavelength conversion particles are mixed with a first base resin, but it is not limited thereto. Each of the wavelength conversion layers QDL may be formed in the plurality of openings OP1 and may overlap the plurality of light emission areas.

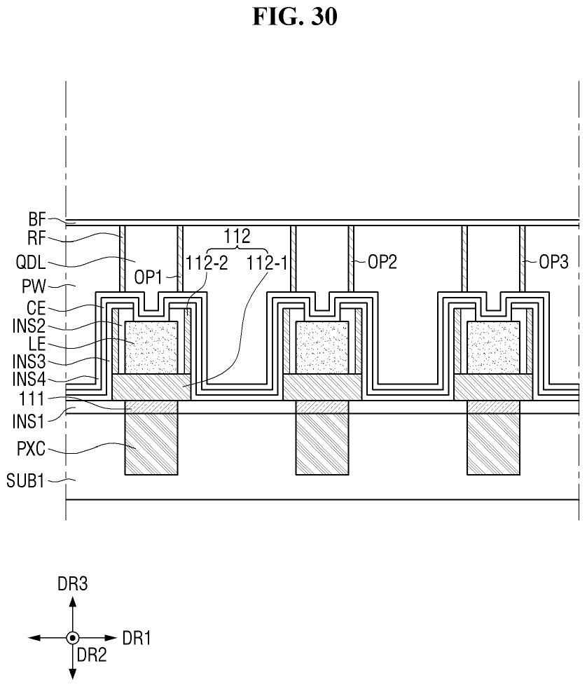

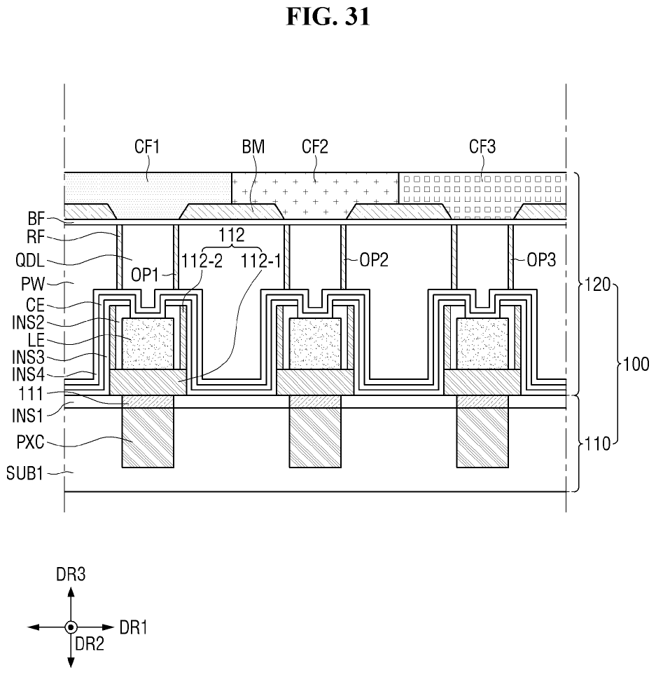

As shown in FIGS. 30 to 31, a protective layer BF and a plurality of color filters CF1, CF2, and CF3 are formed (S200 of FIG. 32)

As shown in FIG. 30, the protective layer BF is formed to cover the upper surface of the partition wall PW, the upper surface of the wavelength conversion layer QDL and the upper surface of the reflective film RF.

Then, a light blocking member BM is formed on the partition wall PW as shown in FIG. 31. The light blocking member BM is formed by coating a light blocking material and patterning the same. The light blocking member BM is formed to overlap the non-light emission area NEA and not to overlap the light emission areas EA1 and EA2. Then, the color filter CF1 is formed on the wavelength conversion layer QDL partitioned by the light blocking member BM. The color filter CF1 may be formed by a photo process. A thickness of the color filter CF1 may be about 1 μm or less but is not limited thereto. Similarly, the other color filters are formed to overlap the respective openings through a patterning process.

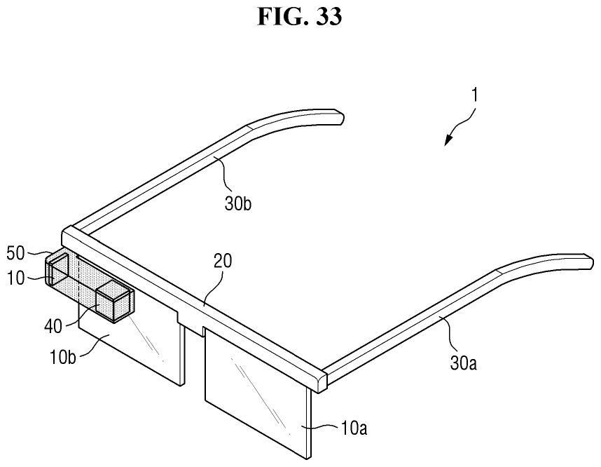

FIG. 33 is a view illustrating a virtual reality device including a display device according to one embodiment. In FIG. 33, a virtual reality device 1 to which a display device 10 according to one embodiment is applied is shown.

Referring to FIG. 33, the virtual reality device 1 according to one embodiment may be a glasses-type device. The virtual reality device 1 according to one embodiment may include a display device 10, a left-eye lens 10a, a right-eye lens a support frame 20, glasses frame legs 30a and 30b, a reflection member 40, and a display device accommodating portion 50.

Although FIG. 33 illustrates the virtual reality device 1 that includes glasses frame legs 30a and 30b, the virtual reality device 1 according to another embodiment may be applied to a head mounted display including a head mounting band, which may be mounted on a head, instead of the glasses frame legs 30a and 30b. That is, the virtual reality device 1 is not limited to that shown in FIG. 33 and is applicable to various electronic devices in various forms.

The display device accommodating portion 50 may include a display device 10 and a reflection member 40. The image displayed on the display device 10 may be reflected by the reflection member 40 and provided to a user's right eye through the right-eye lens 10b. In this manner, the user may view a virtual reality image displayed on the display device 10 through the right eye.

Although FIG. 33 illustrates that the display device accommodating portion 50 is disposed at a right end of the support frame 20, the present disclosure is not limited thereto. For example, the display device accommodating portion 50 may be disposed at a left end of the support frame 20, and in such an embodiment, the image displayed on the display device 10 may be reflected by the reflection member 40 and provided to the user's left eye through the left-eye lens 10a. In this manner, the user may view the virtual reality image displayed on the display device 10 through the left eye. In another embodiment, the display device accommodating portion 50 may be disposed at both the left end and the right end of the support frame 20, and in this manner, the user may view the virtual reality image displayed on the display device 10 through both the left eye and the right eye.

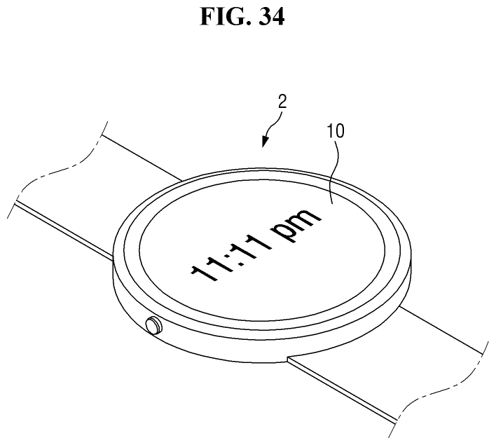

FIG. 34 is a view illustrating a smart device including a display device according to one embodiment.

Referring to FIG. 34, a display device 10 according to one embodiment may be applied to a smart watch 2, which is a type of smart device.

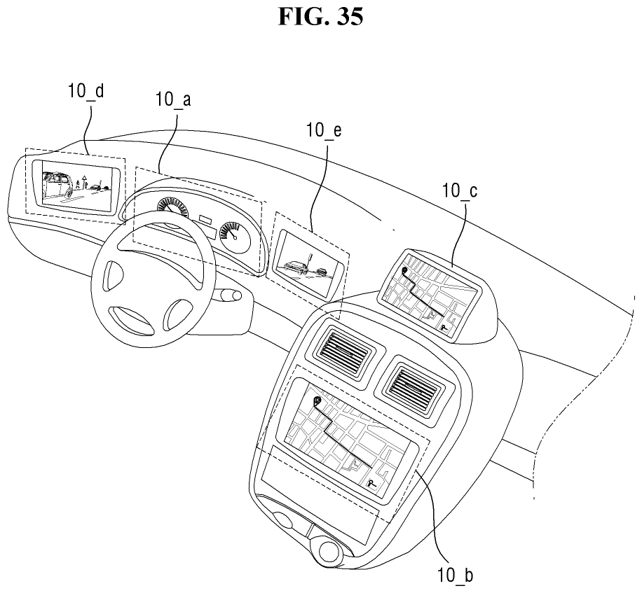

FIG. 35 is a view illustrating a vehicle dashboard and a center fascia including display devices according to one embodiment. A vehicle to which display devices 10 according to one embodiment are applied is shown in FIG. 35.

Referring to FIG. 35, the display devices 10_a, 10_b and 10_c according to one embodiment may be applied to a dashboard of the vehicle, applied to a center fascia of the vehicle, or applied to a center information display (CID) disposed on the dashboard of the vehicle. In some embodiments, the display devices 10_a, 10_b and 10_c may be used as a display devices. In addition, the display devices 10_d and 10_e according to one embodiment may be applied to a room mirror display that replaces a side mirror of the vehicle.

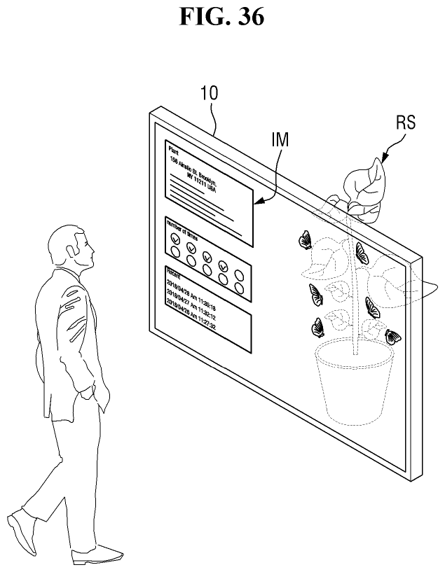

FIG. 36 is a view illustrating a transparent display device including a display device according to one embodiment.

Referring to FIG. 36, a display device 10 according to one embodiment may be applied to the transparent display device. The transparent display device may display an image IM and, at the same time, may transmit light. Therefore, a user located on a front surface of the transparent display device may not only view the image IM displayed on the display device 10 but may also view an object RS or background located on a rear surface of the transparent display device. When the display device 10 is applied to the transparent display device, the first substrate SUB1 of the display device 10, shown in, for example, FIG. 5, may include a light transmitting portion configured to transmit light or may be formed of a light transmissive material.

However, aspects and features of the present disclosure are not limited to those set forth herein. The above and other aspects and features of the present disclosure will become more apparent to one of ordinary skill in the art to which the disclosure pertains by referencing the claims, with equivalents thereof to be included within the scope thereof.

What is claimed is:

1. A display device comprising:
a substrate;
pixel electrodes on the substrate;
light emitting elements on the pixel electrodes and extending in a thickness direction of the substrate;
a first insulating layer extending around sides of the light emitting element; and
a connection electrode between one of the pixel electrodes and a corresponding one of the light emitting elements, the connection electrode comprising:
a connection portion bonding the pixel electrode to the light emitting element; and
a reflection portion integral with the connection portion and extending around the sides of the light emitting element on the first insulating layer.

2. The display device of claim 1, wherein the connection portion and the reflection portion comprise the same material.

3. The display device of claim 2, wherein the connection portion and the reflection portion comprise gold.

4. The display device of claim 3, wherein the connection portion has a first connection portion contacting the one of the pixel electrodes and a second connection portion on the first connection portion.

5. The display device of claim 4, wherein the second connection portion has a gold content ratio that is higher than that of the first connection portion.

6. The display device of claim 1, further comprising a second insulating layer on an upper surface and sides of the reflection portion and sides of the connection portion.

7. The display device of claim 6, further comprising a common electrode on the light emitting elements and the second insulating layer.

8. The display device of claim 7, further comprising a planarization layer between the pixel electrodes,
wherein the second insulating layer is on the planarization layer.

9. The display device of claim 7, further comprising:
partition walls partitioning light emission areas and a non-light emission area; and
a wavelength conversion layer between the partition walls and overlapping the light emitting elements in the light emission areas.

10. The display device of claim 9, further comprising:
a third insulating layer between the wavelength conversion layer and the common electrode; and
a reflective film between the wavelength conversion layer and the partition walls.

11. The display device of claim 10, wherein the reflective film comprises a reflective metal.

12. The display device of claim 9, further comprising:
a light blocking member on the partition walls; and
color filters on the wavelength conversion layer.

13. The display device of claim 1, wherein the light emitting elements comprise a first semiconductor layer, an electron blocking layer, an active layer, a superlattice layer, and a second semiconductor layer that are sequentially stacked in the thickness direction of the substrate.

14. A display device comprising:
a substrate;
pixel electrodes on a substrate;
light emitting elements on the pixel electrodes and extending in a thickness direction of the substrate;
a first insulating layer extending around sides of the light emitting element; and
a connection electrode between one of the pixel electrodes and a corresponding one of the light emitting elements, the connection electrode having a connection portion bonding the pixel electrode to the light emitting element and a reflection portion comprising the same material as the connection portion and extending around the sides of the light emitting element on the first insulating layer.

15. The display device of claim 14, wherein the connection portion and the reflection portion comprise gold.

16. The display device of claim 14, further comprising:
a second insulating layer on an upper surface and sides of the reflection portion and sides of the connection portion; and
a common electrode on the light emitting elements and the second insulating layer.

17. The display device of claim 16, further comprising:
partition walls partitioning light emission areas and a non-light emission area; and
a wavelength conversion layer between the partition walls and overlapping the light emitting elements.

18. A method for manufacturing a display device, the method comprising:
forming a first connection electrode layer on a first substrate;
forming a second connection electrode layer on a light emitting material layer on a second substrate;
bonding the first connection electrode layer to the second connection electrode layer to form a connection electrode layer;
removing the second substrate;
forming a mask pattern on the light emitting material layer;
etching the light emitting material layer according to the mask pattern to form light emitting elements;
forming a first insulating layer on sides of the light emitting element;
forming a connection portion by performing sputtering etching for the connection electrode layer;
forming a reflection portion by adhering a non-volatile material from the connection electrode layer to the first insulating layer during the sputtering etching;
forming a second insulating layer on sides of the connection portion and an upper surface and sides of the reflection portion;
forming a common electrode on an upper surface of each of the light emitting elements and the second insulation layer;
forming partition walls on a non-light emission area; and
forming a wavelength conversion layer on the common electrode between the partition walls, the wavelength conversion layer being configured to convert a wavelength of light emitted from the light emitting elements.

19. The method of claim 18, wherein the connection electrode layer comprises gold.

20. The method of claim 18, wherein the sputtering etching is performed at a temperature in a range of 20° C. to 100° C.
